(19) United States
(12) Patent Application Publication
(10) Pub. No.: US 2025/0351682 A1
(43) Pub. Date: Nov. 13, 2025

(54) DISPLAY DEVICE AND ELECTRONIC DEVICE INCLUDING THE SAME

(71) Applicant: Samsung Display Co., LTD., Yongin-si (KR)

(72) Inventors: Dong Hee SHIN, Yongin-si (KR); Sun Kwun SON, Yongin-si (KR); Na Hyeon CHA, Yongin-si (KR)

(73) Assignee: Samsung Display Co., LTD., Yongin-si (KR)

(21) Appl. No.: 19/028,910

(22) Filed: Jan. 17, 2025

(30) Foreign Application Priority Data
May 8, 2024 (KR) 10-2024-0060803

(51) Int. Cl. H10K 59/124; H10K 59/122; H10K 59/131

(52) U.S. Cl. CPC H10K 59/124; H10K 59/122; H10K 59/131

(57) ABSTRACT

A display device includes a pixel circuit layer including a first via insulating layer and a second via insulating layer covering the first via insulating layer; an anode electrode disposed on the second via insulating layer; and a bank layer including a pixel opening exposing a portion of the anode electrode. The first via insulating layer includes a hole pattern that penetrates the first via insulating layer and overlaps the pixel opening in a plan view, and an upper surface of the anode electrode has an inclination in an area overlapping the hole pattern.

### CROSS-REFERENCE TO RELATED APPLICATION(S)

This application claims priority to and benefits of Korean Patent Application No. 10-2024-0060803 under 35 U.S.C. § 119 filed in the Korean Intellectual Property Office on May 8, 2024, the entire contents of which are incorporated herein by reference.

### BACKGROUND

### 1. Technical Field

The disclosure relates to a display device and an electronic device including the display device.

### 2. Description of the Related Art

Recently, as interest in an information display is increasing research and development for display devices are continuously conducted.

It is to be understood that this background of the technology section is, in part, intended to provide useful background for understanding the technology. However, this background of the technology section may also include ideas, concepts, or recognitions that were not part of what was known or appreciated by those skilled in the pertinent art prior to a corresponding effective filing date of the subject matter disclosed herein.

### SUMMARY

The disclosure relates to a display device with improved side visibility.

An embodiment of the disclosure provides a display device that includes a pixel circuit layer including a first via insulating layer and a second via insulating layer covering the first via insulating layer; an anode electrode disposed on the second via insulating layer; and a bank layer including a pixel opening exposing a portion of the anode electrode, wherein the first via insulating layer includes a hole pattern that penetrates the first via insulating layer and overlaps the pixel opening in a plan view, and an upper surface of the anode electrode has an inclination in an area overlapping the hole pattern.

The second via insulating layer may fill the hole pattern of the first via insulating layer.

An upper surface of the second via insulating layer may have an inclination in the area overlapping the hole pattern.

The pixel opening may be substantially circular in a plan view.

The hole pattern may have a substantially donut shape or a substantially annular shape in a plan view.

The hole pattern may be substantially symmetrical with respect to a center portion of the pixel opening in a plan view.

An additional hole pattern penetrating the first via insulating layer may be included in the first via insulating layer, and an upper surface of the anode electrode may have an inclination in an area overlapping the additional hole pattern.

The additional hole pattern may be surrounded by the hole pattern in a plan view.

The second via insulating layer may fill the additional hole pattern of the first via insulating layer.

An upper surface of the second via insulating layer may have an inclination in the area overlapping the additional hole pattern.

The additional hole pattern may be disposed at a center portion of the pixel opening in a plan view.

The display device may further include a light emitting layer disposed on the anode electrode in the pixel opening.

In the area overlapping the hole pattern, an upper surface of the light emitting layer may have an inclination.

An embodiment of the disclosure provides a display device that includes a pixel circuit layer including a first via insulating layer and a second via insulating layer covering the first via insulating layer; an anode electrode disposed on the second via insulating layer; and a bank layer including a pixel opening exposing a portion of the anode electrode, wherein the first via insulating layer includes a plurality of hole patterns that penetrate the first via insulating layer and overlap the pixel opening in a plan view, and an upper surface of the anode electrode has an inclination in areas overlapping the plurality of hole patterns.

The second via insulating layer may fill the plurality of hole patterns of the first via insulating layer.

An upper surface of the second via insulating layer may have an inclination in areas that overlap the plurality of hole patterns.

The pixel opening may be substantially circular in a plan view.

Each of the plurality of hole patterns may be substantially circular in a plan view.

In a plan view, the plurality of hole patterns may include a central hole pattern disposed at a center portion of the pixel opening, and peripheral hole patterns disposed around the central hole pattern.

The peripheral hole patterns may be symmetrically disposed with respect to the central hole pattern in a plan view.

An embodiment of the disclosure provides an electronic device that includes a processor to provide input image data and a display device to display an image based on the input image data, wherein the display device includes a pixel circuit layer including a first via insulating layer and a second via insulating layer covering the first via insulating layer; an anode electrode disposed on the second via insulating layer; and a bank layer including a pixel opening exposing a portion of the anode electrode, wherein the first via insulating layer includes a plurality of hole patterns that penetrate the first via insulating layer and overlap the pixel opening in a plan view, and an upper surface of the anode electrode has an inclination in areas overlapping the plurality of hole patterns.

The second via insulating layer may fill the hole pattern of the first via insulating layer. The pixel opening may be substantially circular in a plan view.

In the display device according to the disclosure, the first via insulating layer may include a hole pattern penetrating the first via insulating layer and overlapping a pixel opening in a plan view, and the upper surface of the anode electrode may be inclined in an area overlapping the hole pattern.

As the upper surface of the anode electrode is inclined, light generated by the display device may be reflected by the inclined surface of the anode electrode. Accordingly, light of substantially uniform luminance may be provided regardless of the direction in which the user of the display device looks at the display device.

As the hole pattern for forming an inclination on the upper surface of the anode electrode is formed to penetrate the first via insulating layer, the difficulty of the process for forming the hole pattern may decrease. For example, compared to in case that the hole pattern is provided so as not to penetrate the first via insulating layer (for example, in case that a concave portion that does not penetrate the first via insulating layer is formed in the first via insulating layer), the process difficulty may be lower in case that the hole pattern is provided so as to penetrate the first via insulating layer.

### BRIEF DESCRIPTION OF THE DRAWINGS

The above and other aspects and features of the disclosure will become more apparent by describing in detail embodiments thereof with reference to the attached drawings, in which:

FIG. 1 illustrates a block diagram of a display device according to embodiments.

FIG. 2 illustrates a block diagram of one of sub-pixels included in the display device of FIG. 1.

FIG. 3 illustrates a schematic top plan view of a display panel configuring the display device of FIG. 1.

FIG. 4 illustrates a schematic cross-sectional view of the display panel of FIG. 3 according to an embodiment.

FIG. 5 illustrates a schematic cross-sectional view of the display panel of FIG. 3 according to an embodiment.

FIG. 6 illustrates a schematic top plan view for explaining a first embodiment of one of pixels included in the display panel of FIG. 3.

FIG. 7 illustrates a schematic cross-sectional view taken along line I1-I2 of FIG. 6.

FIG. 8 illustrates a schematic cross-sectional view taken along line I3-I4 of FIG. 6.

FIG. 9 illustrates a schematic cross-sectional view taken along line I5-I6 of FIG. 6.

FIG. 10 illustrates a schematic top plan view for explaining a second embodiment of one of pixels included in the display panel of FIG. 3.

FIG. 11 illustrates a schematic cross-sectional view taken along line I7-I8 of FIG. 10.

FIG. 12 illustrates a schematic cross-sectional view taken along line I9-I10 of FIG. 10.

FIG. 13 illustrates a schematic top plan view for explaining a third embodiment of one of pixels included in the display panel of FIG. 3.

FIG. 14 illustrates a schematic cross-sectional view taken along line I11-I12 of FIG. 13.

FIG. 15 illustrates a schematic cross-sectional view taken along line I13-I14 of FIG. 13.

FIG. 16 illustrates a schematic cross-sectional view taken along line I15-I16 of FIG. 13.

FIG. 17 is a block diagram of an electronic device according to an embodiment.

FIG. 18 shows schematic views of various embodiments of an electronic device.

### DETAILED DESCRIPTION OF THE EMBODIMENTS

Hereinafter, example embodiments will be described in detail with reference to the accompanying drawings. The following description is intended to provide a disclosure to enable understanding to one of ordinary skill in the art. The disclosure may be embodied in different forms and is not limited to the embodiments set forth herein. The embodiments described herein are provided for the purpose of describing the disclosure in detail for those skilled in the art to readily practice it.

Throughout the specification, when it is described that an element is “connected” to another element, this includes not only being “directly connected”, but also being “indirectly connected” with another device therebetween. The terms used herein are for the purpose of describing embodiments and are not intended to limit the scope of the disclosure.

As used herein, the singular forms, “a,” “an,” and “the” are intended to include the plural forms as well, unless the context clearly indicates otherwise.

In the specification and the claims, the term “and/or” is intended to include any combination of the terms “and” and “or” for the purpose of its meaning and interpretation. For example, “A and/or B” may be understood to mean “A, B, or A and B.” The terms “and” and “or” may be used in the conjunctive or disjunctive sense and may be understood to be equivalent to “and/or.”

The terms “comprises,” “comprising,” “includes,” and/or “including,” “has,” “have,” and/or “having,” and variations thereof when used in this specification, specify the presence of stated features, integers, steps, operations, elements, components, and/or groups thereof, but do not preclude the presence or addition of one or more other features, integers, steps, operations, elements, components, and/or groups thereof.

The terms “overlap” or “overlapped” mean that a first object may be above or below or to a side of a second object, and vice versa. Additionally, the term “overlap” may include layer, stack, face or facing, extending over, covering, or partly covering or any other suitable term as would be appreciated and understood by those of ordinary skill in the art.

The terms “face” and “facing” mean that a first element may directly or indirectly oppose a second element. In a case in which a third element intervenes between the first and second element, the first and second element may be understood as being indirectly opposed to one another, although still facing each other.

When an element is described as ‘not overlapping’ or ‘to not overlap’ another element, this may include that the elements are spaced apart from each other, offset from each other, or set aside from each other or any other suitable term as would be appreciated and understood by those of ordinary skill in the art.

For the purposes of this disclosure, “at least one of X, Y, and Z” and “at least one selected from the array consisting of X, Y, and Z” may be construed as X only, Y only, Z only, or any combination of two or more of X, Y, and Z, such as, for instance, XYZ, XYY, YZ, and ZZ.

Although the terms first, second, etc. may be used herein to describe various constituent elements, these constituent elements should not be limited by these terms. These terms are used to distinguish one constituent element from another. Thus, a first constituent element discussed below could be termed a second constituent element without departing from the teachings of the disclosure.

Spatially relative terms, such as “beneath,” “below,” “lower,” “above,” “upper,” and the like, may be used herein for descriptive purposes, and, thereby, to describe one element or feature's relationship to another element(s) or feature(s) as illustrated in the drawings. Spatially relative terms are intended to encompass different orientations of an apparatus in use, operation, and/or manufacture in addition to the orientation depicted in the drawings. For example, if the apparatus in the drawings is turned over, elements described as “below” or “beneath” other elements or features would then be oriented “above” the other elements or features. Thus, the term “below” can encompass both an orientation of above and below. Furthermore, the apparatus may be otherwise oriented (for example, rotated 90 degrees or at other orientations), and, as such, the spatially relative descriptors used herein interpreted accordingly.

Various embodiments are described herein with reference to sectional illustrations that are schematic illustrations of given embodiments. As such, variations from the shapes of the illustrations as a result, for example, of manufacturing techniques and/or tolerances, are to be expected. Thus, embodiments disclosed herein should not be construed as limited to the illustrated shapes of regions, but are to include deviations in shapes that result from, for instance, manufacturing. Thus, the regions illustrated in the drawings are schematic in nature and their shapes are not intended to illustrate the actual shape of a region of a device and are not intended to be limiting.

“About” or “approximately” as used herein is inclusive of the stated value and means within an acceptable range of deviation for the particular value as determined by one of ordinary skill in the art, considering the measurement in question and the error associated with measurement of the particular quantity (i.e., the limitations of the measurement system). For example, “about” may mean within one or more standard deviations, or within +30%, 20%, 10%, 5% of the stated value.

Unless otherwise defined or implied herein, all terms (including technical and scientific terms) used herein have the same meaning as commonly understood by one of ordinary skill in the art to which the disclosure pertains. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

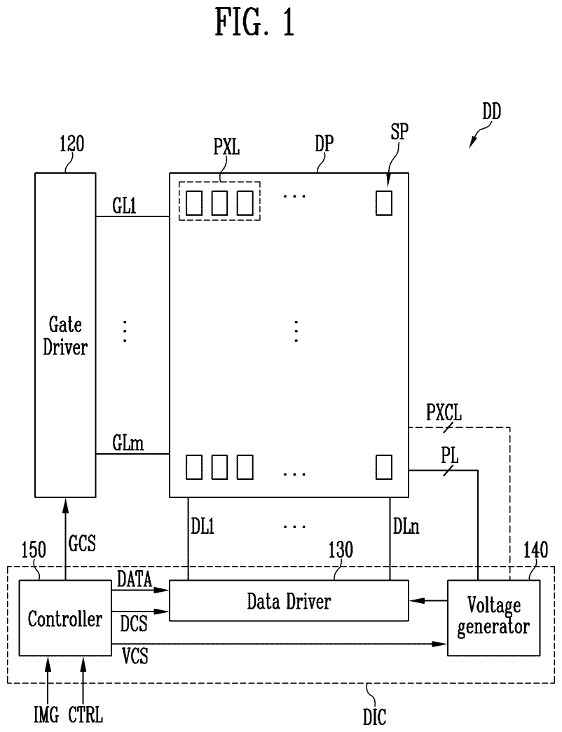

FIG. 1 illustrates a block diagram of a display device according to embodiments.

Referring to FIG. 1, a display device DD may include a display panel DP, a gate driver 120, a data driver 130, a voltage generator 140, and a controller 150.

The display panel DP may include sub-pixels SP. The sub-pixels SP may be connected to the gate driver 120 through first to m-th gate lines GL1 to GLm. The sub-pixels SP may be connected to the data driver 130 through first to n-th data lines DL1 to DLn.

The sub-pixels SP may generate light of two or more colors. For example, the sub-pixels SP may respectively generate light of a color, such as red, green, blue, cyan, magenta, yellow, or the like within the spirit and the scope of the disclosure.

Two or more of the sub-pixels SP may configure one pixel PXL. For example, the pixel PXL may include three sub-pixels as shown in FIG. 1. The pixel PXL may emit light of various colors and various luminance depending on a combination of light emitted from the sub-pixels included in the pixel PXL.

The gate driver 120 may be connected to the sub-pixels SP arranged or disposed in a row direction through the first to m-th gate lines GL1 to GLm. The gate driver 120 may output gate signals to the first to m-th gate lines GL1 to GLm in response to a gate control signal GCS. In embodiments, the gate control signal GCS may include a start signal indicating the start of each frame, a horizontal synchronization signal, and the like within the spirit and the scope of the disclosure.

The gate driver 120 may be disposed on one side or a side of the display panel DP. However, embodiments are not limited thereto. For example, the gate driver 120 may be divided into two or more drivers that are physically and/or logically divided, and these drivers may be disposed on one side or a side of the display panel DP and the other side opposite to the one side or the side. As described above, the gate driver 120 may be disposed around the display panel DP in various forms according to the embodiments.

The data driver 130 may be connected to the sub-pixels SP arranged or disposed in a column direction through the first to n-th data lines DL1 to DLn. The data driver 130 may receive image data (DATA) and a data control signal DCS from the controller 150. The data driver 130 may operate in response to the data control signal DCS. In embodiments, the data control signal DCS may include a source start signal, a source shift clock, a source output enable signal, and the like within the spirit and the scope of the disclosure.

The data driver 130 may receive voltages from the voltage generator 140. The data driver 130 may use the received voltages to apply data signals having grayscale voltages corresponding to the image data (DATA) to the first to n-th data lines DL1 to DLn. In case that a gate signal is applied to each of the first to m-th gate lines GL1 to GLm, data signals corresponding to the image data DATA may be applied to the data lines DL1 to DLm. Accordingly, the sub-pixels SP may generate light corresponding to the data signals, and the display panel DP may display an image.

In an embodiment, the gate driver 120 and the data driver 130 may include complementary metal-oxide semiconductor (CMOS) circuit elements.

The voltage generator 140 may operate in response to a voltage control signal VCS from the controller 150. The voltage generator 140 may be configured to generate voltages and provide the generated voltages to components of the display device DD, such as the gate driver 120, the data driver 130, and the controller 150. The voltage generator 140 may generate voltages by receiving an input voltage from the outside of the display device DD and regulating the received voltage.

The voltage generator 140 may generate a first power voltage and a second power voltage. The generated first and second power voltages may be provided to the sub-pixels SP through the power lines PL. In other embodiments, at least one of the first and second power voltages may be provided from the outside of the display device DD.

The voltage generator 140 may provide various voltages and/or signals. For example, the voltage generator 140 may provide one or more initialization voltages applied to the sub-pixels SP. For example, during a sensing operation to sense electrical characteristics of transistors and/or light emitting elements of the sub-pixels SP, a selectable reference voltage may be applied to the first to n-th data lines DL1 to DLn, and the voltage generator 140 may generate the reference voltage to transmit it to the data driver 130. For example, during a display operation for displaying an image on the display panel DP, common pixel control signals may be applied to the sub-pixels SP, and the voltage generator 140 may generate the pixel control signals. In embodiments, the voltage generator 140 may provide pixel control signals to the sub-pixels SP through a pixel control lines PXCL. FIG. 1 illustrates that the pixel control lines PXCL are connected between the voltage generator 140 and the display panel DP, but the embodiments are not limited thereto. For example, the pixel control lines PXCL may be connected between the gate driver 120 and the display panel DP. For example, the pixel control signals may be transmitted from the voltage generator 140 to the pixel control lines PXCL through the gate driver 120.

The controller 150 may control various operations of the display device DD. The controller 150 may receive input image data IMG and a control signal CTRL corresponding thereto, from the outside. The controller 150 may provide the gate control signal GCS, the data control signal DCS, and the voltage control signal VCS in response to the control signal CTRL.

The controller 150 may convert the input image data IMG to be suitable for the display device DD or the display panel DP to output the image data DATA. In embodiments, the controller 150 may output the image data DATA by aligning the input image data IMG to be suitable for the sub-pixels SP of a row unit.

Two or more components of the data driver 130, the voltage generator 140, and the controller 150 may be mounted on one integrated circuit. As shown in FIG. 1, the data driver 130, the voltage generator 140, and the controller 150 may be included in a driver integrated circuit DIC. For example, the data driver 130, the voltage generator 140, and the controller 150 may be functionally separate components in a single driver integrated circuit DIC. In other embodiments, at least one of the data driver 130, the voltage generator 140, and the controller 150 may be provided as a component separated from the driver integrated circuit DIC.

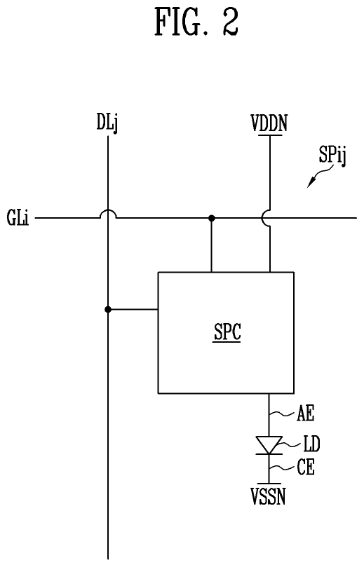

FIG. 2 illustrates a block diagram of one of sub-pixels included in the display device of FIG. 1. In FIG. 2, among the sub-pixels SP of FIG. 1, a sub-pixel SPij disposed in an i-th row (I is an integer greater than or equal to 1 and less than or equal to m) and a j-th column (j is an integer greater than or equal to 1 and less than or equal to n) is illustrated as an example.

Referring to FIG. 2, the sub-pixel SPij may include a sub-pixel circuit SPC and a light emitting element LD.

The light emitting element LD may be connected between a first power voltage node VDDN and a second power voltage node VSSN. The first power voltage node VDDN may be connected to one of the power lines PL in FIG. 1 to receive the first power voltage. The second power voltage node VSSN may be connected to another one of the power lines PL in FIG. 1 to receive the second power voltage. The first power voltage may have a higher level than the second power voltage.

The light emitting element LD may be connected between the anode electrode AE and the cathode electrode CE. The anode electrode AE may be connected to the first power voltage node VDDN through the sub-pixel circuit SPC. For example, the anode electrode AE may be connected to the first power voltage node VDDN through one or more transistors included in the sub-pixel circuit SPC. The cathode electrode CE may be connected to the second power voltage node VSSN. The light emitting element LD may be configured to emit light according to a current flowing from the anode electrode AE to the cathode electrode CE.

The sub-pixel circuit SPC may be connected to an i-th gate line GLi of the first to m-th gate lines GL1 to GLm of FIG. 1 and a j-th data line DLj of the first to n-th data lines DL1 to DLn of FIG. 1. In response to the gate signal received through the i-th gate line GLi, the sub-pixel circuit SPC may control the light emitting element LD to emit light according to the data signal received through the j-th data line DLj. In embodiments, the sub-pixel circuit SPC may be further connected to the pixel control lines PXCL of FIG. 1. For example, the sub-pixel circuit SPC may control the light emitting element LD in further response to pixel control signals received through the pixel control lines PXCL.

For these operations, the sub-pixel circuit SPC may include circuit elements, for example transistors and one or more capacitors.

The transistors of the sub-pixel circuit SPC may include P-type transistors and/or N-type transistors. In embodiments, the transistors of the sub-pixel circuit SPC may include a metal oxide semiconductor field effect transistor (MOSFET). In embodiments, the transistors of the sub-pixel circuit SPC may include an amorphous silicon semiconductor, a monocrystalline silicon semiconductor, a polycrystalline silicon semiconductor, and an oxide semiconductor.

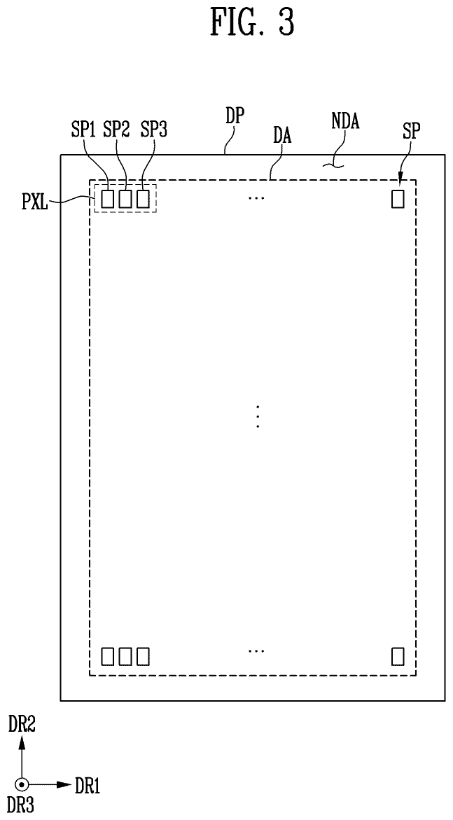

FIG. 3 illustrates a schematic top plan view of a display panel configuring the display device of FIG. 1.

Referring to FIG. 3, the display panel DP may include a display area DA and a non-display area NDA. The display panel DP may display an image through the display area DA. The non-display area NDA may be disposed around the display area DA.

The display panel DP may include sub-pixels SP disposed in the display area DA. The sub-pixels SP may be arranged or disposed along a first direction DR1 and a second direction DR2 that intersects the first direction DR1. For example, the sub-pixels SP may be arranged or disposed in a matrix format along the first direction DR1 and the second direction DR2. As another example, the sub-pixels SP may be arranged or disposed in a zigzag form along first direction DR1 and second direction DR2. The arrangement of the sub-pixels SP may vary in an embodiment. The first direction DR1 may be a row direction, and the second direction DR2 may be a column direction.

Two or more of the sub-pixels SP may configure one pixel PXL. FIG. 3 illustrates that the pixel PXL may include three sub-pixels SP1, SP2, and SP3, but embodiments are not limited thereto. For example, the pixel PXL may include two sub-pixels. Hereinafter, for better understanding and ease of description, it is assumed that the pixel PXL may include the first to third sub-pixels SP1, SP2, and SP3.

Each of the first to third sub-pixels SP1, SP2, and SP3 may generate one of various colors such as red, green, blue, cyan, magenta, and yellow. For example, the first sub-pixel SP1 may be configured to generate red-colored light, the second sub-pixel SP2 may be configured to generate green-colored light, and the third sub-pixel SP3 may be configured to generate blue-colored light, but embodiments are not limited thereto.

Each of the first to third sub-pixels SP1, SP2, and SP3 may include at least one light emitting element configured to generate light. In embodiments, the light emitting elements of the first to third sub-pixels SP1, SP2, and SP3 may generate light of different colors. For example, the light emitting elements of the first to third sub-pixels SP1, SP2, and SP3 may generate light of red, green, and blue colors, respectively.

As the display panel DP, for example, a display panel capable of self-light emitting, such as an organic light emitting display panel (OLED panel) that uses an organic light emitting diode as a light emitting element, may be used.

A constituent element to control the sub-pixels SP may be disposed in the non-display area NDA. Wires connected to the sub-pixels SP, for example, the first to m-th gate lines GL1 to GLm, the first to n-th data lines DL1 to DLn, the power lines PL, and the pixel control lines PXCL shown in FIG. 1 may be disposed in the non-display area NDA.

At least one of the gate driver 120, the data driver 130, the voltage generator 140, and the controller 150 in FIG. 1 may be disposed in the non-display area NDA of the display panel DP. In embodiments, the gate driver 120 may be disposed in the non-display area NDA. For example, the data driver 130, the voltage generator 140, and the controller 150 may be implemented as the driver integrated circuit DIC of FIG. 1 separated from the display panel DP, and the driver integrated circuit DIC may be connected to wires disposed in the non-display area NDA. In other embodiments, the gate driver 120 may be implemented as one integrated circuit separated from the display panel DP together with the data driver 130, the voltage generator 140, and the controller 150.

In embodiments, the display area DA may have various shapes. The display area DA may have a closed-loop shape including sides of a straight line and/or a curved line. For example, the display area DA may have shapes such as a polygonal shape, a circular shape, a semicircular, and an elliptical shape.

In embodiments, the display panel DP may have a flat display surface. In other embodiments, the display panel DP may have a display surface that is at least partially round. In embodiments, the display panel DP may be bendable, foldable, or rollable. In these cases, the display panel DP and/or the substrate of the display panel DP may include materials with flexible properties.

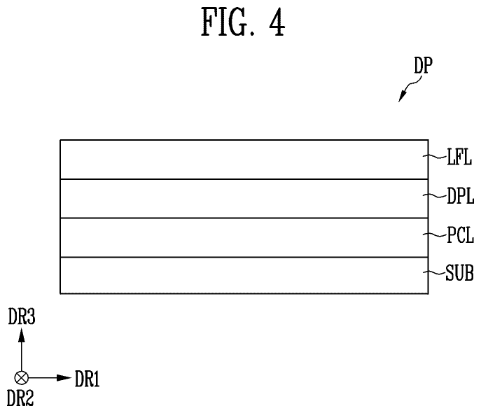

FIG. 4 illustrates a schematic cross-sectional view of the display panel of FIG. 3 according to an embodiment.

Referring to FIG. 4, the display panel DP may include a substrate SUB, and a pixel circuit layer PCL, a display element layer DPL, and a light functional layer LFL, which may be sequentially stacked on each other on the substrate SUB in a third direction DR3 intersecting the first and second directions DR1 and DR2.

The substrate SUB may be made of an insulating material such as glass or a resin. For example, the substrate SUB may include a glass substrate. As another example, the substrate SUB may include a polyimide (PI) substrate. As another example, the substrate SUB may include a silicon wafer substrate formed using a semiconductor process.

In embodiments, the substrate SUB may be made of a flexible material to be bendable or foldable, and may have a single-layered structure or a multi-layered structure. For example, the flexible material may include at least one of polystyrene, polyvinyl alcohol, polymethyl methacrylate, polyethersulfone, polyacrylate, polyetherimide, polyethylene naphthalate, polyethylene terephthalate, polyphenylene sulfide, polyarylate, polyimide, polycarbonate, triacetate cellulose, and cellulose acetate propionate. However, embodiments are not limited thereto.

The pixel circuit layer PCL may be disposed on the substrate SUB. The pixel circuit layer PCL may include insulating layers and semiconductor patterns and conductive patterns disposed between the insulating layers. The conductive patterns of the pixel circuit layer PCL may function as circuit elements, wires, and the like within the spirit and the scope of the disclosure.

The circuit elements of the pixel circuit layer PCL may configure the sub-pixel circuit SPC of each of the sub-pixels SP of FIG. 3. In other words, the circuit elements of the pixel circuit layer PCL may be provided as transistors and one or more capacitors of the sub-pixel circuit SPC.

The wires of the pixel circuit layer PCL may include wires connected to the sub-pixels SP. The wires of the pixel circuit layer PCL may include various signal lines and/or voltage lines required to drive the display element layer DPL.

The display element layer DPL may be disposed on the pixel circuit layer PCL. The display element layer DPL may include light emitting elements of the sub-pixels SP.

The light functional layer LFL may be disposed on the display element layer DPL. The light functional layer LFL may include light conversion patterns having color conversion particles and/or scattering particles. For example, the color conversion particles may include quantum dots. The quantum dots may change the wavelength (or color) of light emitted from the display element layer DPL. The light functional layer LFL may further include light scattering patterns with scattering particles. In embodiments, the light conversion patterns and the light scattering patterns may be omitted.

The light functional layer LFL may further include a color filter layer including color filters. The color filter may selectively transmit light of a given wavelength (or a given color). In embodiments, the color filter layer may be omitted.

A window for protecting an exposed surface (or upper surface) of the display panel DP may be provided on the light functional layer LFL. The window may protect the display panel DP from external impact. The window may be coupled or connected to the light functional layer LFL through an optically transparent adhesive (bonding) member. The window may have a multi-layered structure selected from a glass substrate, a plastic film, and a plastic substrate. The multi-layered structure may be formed through a continuous process or an adhesive process using an adhesive layer. All or a portion of the window may be flexible.

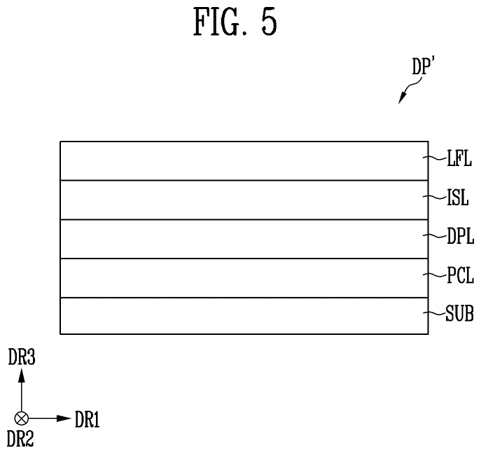

FIG. 5 illustrates a schematic cross-sectional view of the display panel of FIG. 3 according to an embodiment.

Referring to FIG. 5, a display panel DP′ may include a substrate SUB, a pixel circuit layer PCL, a display element layer DPL, an input sensing layer ISL, and a light functional layer LFL. The substrate SUB, the pixel circuit layer PCL, the display element layer DPL, and the light functional layer LFL may be configured to be substantially the same as (or similar to) the substrate SUB, the pixel circuit layer PCL, the display element layer DPL, and the light functional layer LFL described with reference to FIG. 4. Accordingly, descriptions of redundant content are omitted.

The input sensing layer ISL may detect a user input on an upper surface (or display surface) of the display panel DP′. The input sensing layer ISL may include components suitable for sensing an external object such as a user's hand or pen. For example, the input sensing layer ISL may include touch electrodes.

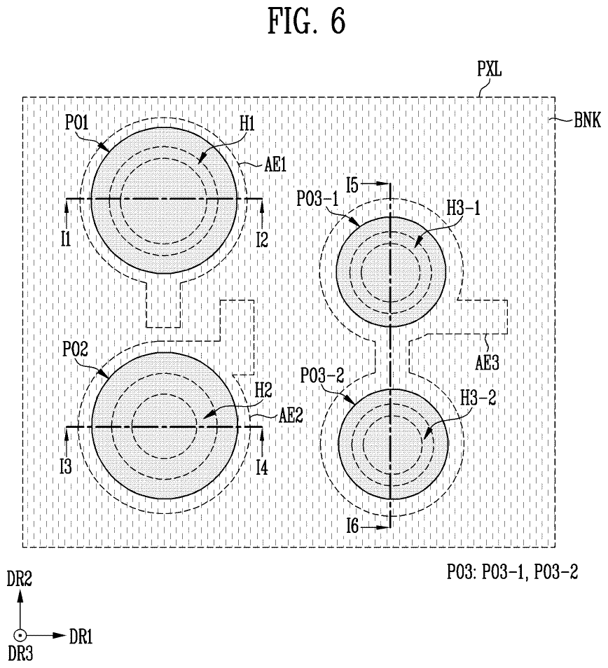

FIG. 6 illustrates a schematic top plan view for explaining a first embodiment of one of pixels included in the display panel of FIG. 3.

Referring to FIG. 6, the pixel PXL may include first to third anode electrodes AE1, AE2, and AE3. The first anode electrode AE1 may be spaced apart from the second anode electrode AE2 in the second direction DR2. The third anode electrode AE3 may be spaced apart from the first and second anode electrodes AE1 and AE2 in the first direction DR1. However, the arrangement of the first to third anode electrodes AE1, AE2, and AE3 is not limited thereto, and may vary according to embodiments. For example, the first to third anode electrodes AE1, AE2, and AE3 may be disposed in a zigzag pattern.

The first anode electrode AE1 may be provided as the anode electrode AE (see FIG. 2) included in the sub-pixel circuit SPC (see FIG. 2) of the first sub-pixel SP1 (see FIG. 3). The second anode electrode AE2 may be provided as the anode electrode AE (see FIG. 2) included in the sub-pixel circuit SPC (see FIG. 2) of the second sub-pixel SP2 (see FIG. 3). The third anode electrode AE3 may be provided as the anode electrode AE (see FIG. 2) included in the sub-pixel circuit SPC (see FIG. 2) of the third sub-pixel SP3 (see FIG. 3).

A bank layer BNK may be disposed on the first to third anode electrodes AE1, AE2, and AE3. The bank layer BNK may define a first pixel opening PO1 exposing a portion of the first anode electrode AE1, a second pixel opening PO2 exposing a portion of the second anode electrode AE2, and a third pixel opening PO3 exposing a portion of the third anode electrode AE3.

Each of the first to third pixel openings PO1, PO2, and PO3 may be circular in a plan view. Accordingly, each of the exposed surfaces of the first to third anode electrodes AE1, AE2, and AE3 exposed by the first to third pixel openings PO1, PO2, and PO3 may be circular in a plan view. Accordingly, light generated by the first to third sub-pixels SP1, SP2, and SP3 including the first to third anode electrodes AE1, AE2, and AE3 may be provided as light having substantially uniform luminance regardless of the direction in which the user of the display device DD looks at the display device DD.

In embodiments, first to third pixel openings PO1, PO2, and PO3 may be provided, each independently. For example, as shown in FIG. 6, the third pixel opening PO3 may include a (3-1)-th pixel opening PO3-1 and a (3-2)-th pixel opening PO3-2. The (3-1)-th pixel opening PO3-1 and the (3-2)-th pixel opening PO3-2 may be spaced apart from each other. Each of the (3-1)-th pixel opening PO3-1 and the (3-2)-th pixel opening PO3-2 may be circular in a plan view. Accordingly, each of the exposed surfaces of the third anode electrode AE3 exposed by the (3-1)-th pixel opening PO3-1 and the (3-2)-th pixel opening PO3-2 may be circular in a plan view.

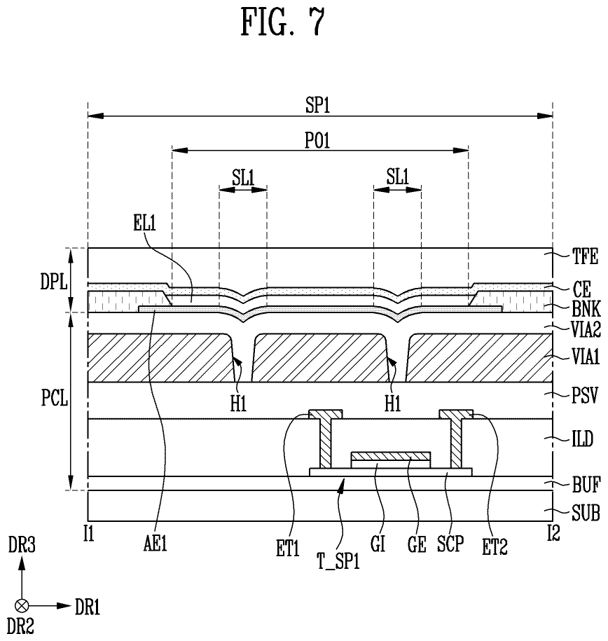

FIG. 7 illustrates a schematic cross-sectional view taken along line I1-I2 of FIG. 6.

Referring to FIG. 6 and FIG. 7, the first sub-pixel SP1 included in the pixel PXL is shown.

The first sub-pixel SP1 may include a substrate SUB, and a pixel circuit layer PCL and a display element layer DPL sequentially stacked on each other on the substrate SUB.

The pixel circuit layer PCL may include insulating layers, semiconductor patterns, and conductive patterns stacked on each other on the substrate SUB. The insulating layers may include a buffer layer BUF, one or more interlayer insulating layers ILD, one or more passivation layers PSV, a first via insulating layer VIA1, and a second via insulating layer VIA2. The semiconductor patterns and the conductive patterns may be disposed between the insulating layers. The conductive patterns may include at least one of copper (Cu), molybdenum (Mo), tungsten (W), aluminum neodymium (AlNd), titanium (Ti), aluminum (Al), and silver (Ag).

As described with reference to FIG. 2, the sub-pixel circuit SPC (see FIG. 2) of the first sub-pixel SP1 may include transistors and one or more capacitors. The semiconductor patterns and conductive patterns of the pixel circuit layer PCL may function as transistors and capacitors of the sub-pixel circuit SPC. The conductive patterns of the pixel circuit layer PCL may further function as wires, for example, the first to m-th gate lines GL1 to GLm, the first to n-th data lines DL1 to DLn, the power lines PL, and the pixel control lines PXCL in FIG. 1.

The buffer layer BUF may be disposed on one surface or a surface of the substrate SUB. The buffer layer BUF may serve to prevent impurities from diffusing into the circuit elements and wires included in the pixel circuit layer PCL. The buffer layer BUF may include an inorganic insulating layer including an inorganic material. In embodiments, the buffer layer BUF may include at least one of metal oxides such as a silicon nitride, a silicon oxide, a silicon oxynitride, and an aluminum oxide. The buffer layer BUF may be provided as a single layer or a multilayer. In case that the buffer layer BUF is provided as the multiple layers, respective layers thereof may be made of a same material or different materials.

In embodiments, one or more barrier layers may be disposed between the substrate SUB and the buffer layer BUF. Each of the barrier layers may include, for example, polyimide.

A first transistor T_SP1 corresponding to the first sub-pixel SP1 may be disposed on the buffer layer BUF. The first transistor T_SP1 may be one of the transistors of the sub-pixel circuit SPC included in the first sub-pixel SP1.

The first transistor T_SP1 may include a semiconductor pattern SCP, a gate electrode GE, a first terminal ET1, and a second terminal ET2. The first terminal ET1 may be one of a source electrode and a drain electrode, and the second terminal ET2 may be the other of the source electrode and the drain electrode. For example, the first terminal ET1 may be the source electrode, and the second terminal ET2 may be the drain electrode.

The semiconductor pattern SCP may be disposed on the buffer layer BUF. The semiconductor pattern SCP may include a first contact area in contact with the first terminal ET1 and a second contact area in contact with the second terminal ET2. An area between the first contact area and the second contact area may be a channel area. The channel area may overlap the gate electrode GE of the first transistor T_SP1. The channel area is a semiconductor pattern that is not substantially doped with impurities, and may be an intrinsic semiconductor. The first contact area and the second contact area may be semiconductor patterns doped with impurities. As the impurities, for example, p-type impurities may be used, but embodiments are not limited thereto.

The semiconductor pattern SCP may include one of various types of semiconductors, for example, one of an amorphous silicon semiconductor, a monocrystalline silicon semiconductor, a polycrystalline silicon semiconductor, a low temperature polysilicon semiconductor, and an oxide semiconductor.

Interlayer insulating layers ILD sequentially stacked on each other on the semiconductor pattern SCP may be disposed. The interlayer insulating layers ILD may be inorganic insulating layers including an inorganic material. For example, each of the interlayer insulating layers ILD may include at least one of metal oxides such as a silicon nitride, a silicon oxide, a silicon oxynitride, and an aluminum oxide. However, the interlayer insulating layers ILD are not limited thereto. For example, one of the interlayer insulating layers ILD may include an organic insulating layer including an organic material.

The interlayer insulating layers ILD may electrically separate conductive patterns and/or semiconductor patterns disposed between the interlayer insulating layers ILD from each other. For example, the interlayer insulating layers ILD may include a gate insulating layer GI disposed on the semiconductor pattern SCP. The gate insulating layer GI may be disposed between the semiconductor pattern SCP and the gate electrode GE so that the semiconductor pattern SCP is spaced apart from the gate electrode GE. In embodiments, the gate insulating layer GI may be entirely provided on the semiconductor pattern SCP and the buffer layer BUF to cover the semiconductor pattern SCP and the buffer layer BUF. As the number of layers required to form conductive patterns and/or semiconductor patterns increases, the number of the interlayer insulating layers ILD may increase.

The gate electrode GE may be disposed on the gate insulating layer GI. The gate electrode GE may overlap the channel area of the semiconductor pattern SCP. In embodiments, the gate electrode GE may be provided as a single layer including at least one of copper (Cu), molybdenum (Mo), tungsten (W), aluminum neodymium (AlNd), titanium (Ti), aluminum (Al), and silver (Ag). In embodiments, the gate electrode GE may be provided as a multilayer including at least one of molybdenum (Mo), titanium (Ti), copper (Cu), aluminum (Al), and silver (Ag), which are low-resistance materials.

The first and second terminals ET1 and ET2 may be disposed on the interlayer insulating layers ILD. The first and second terminals ET1 and ET2 may contact the semiconductor pattern SCP through contact holes penetrating the interlayer insulating layers ILD. The first and second terminals ET1 and ET2 may contact the first and second contact areas of the semiconductor pattern SCP, respectively. Each of the first and second terminals ET1 and ET2 may include at least one of copper (Cu), molybdenum (Mo), tungsten (W), aluminum neodymium (AlNd), titanium (Ti), aluminum (Al), and silver (Ag).

In embodiments, the first transistor T_SP1 may be configured as a low-temperature polysilicon transistor. However, embodiments are not limited thereto. For example, the first transistor T_SP1 may be configured as an oxide semiconductor transistor. In embodiments, the sub-pixel circuit SPC of the first sub-pixel SP1 may include different types of transistors. For example, the first transistor T_SP1 may be configured as a low-temperature polysilicon transistor, and another transistor included in the sub-pixel circuit SPC of the first sub-pixel SP1 may be configured as an oxide semiconductor transistor. For example, the oxide semiconductor of the corresponding oxide semiconductor transistor may be disposed on one of the interlayer insulating layers ILD, rather than the insulating layer in which the semiconductor pattern SCP of the first transistor T_SP1 is disposed.

In FIG. 7, the case in which the first transistor T_SP1 is a transistor with a top gate structure has been described as an example, but the embodiments are not limited thereto. For example, the first transistor T_SP1 may be a transistor with a bottom gate structure. The structure of the first transistor T_SP1 may be variously changed.

At least some of the various wires of the display panel DP and/or the display device DD may be further disposed on the interlayer insulating layers ILD.

A passivation layer PSV may be disposed on the interlayer insulating layers ILD and the first and second terminals ET1 and ET2. The passivation layer may also be referred to as a protective layer or via layer. The passivation layer PSV may protect components disposed under or below the passivation layer PSV, and may provide a flat upper surface. The passivation layer PSV may include an inorganic insulating layer containing an inorganic material and/or an organic insulating layer containing an organic material. The inorganic insulating layer may include, for example, at least one of metal oxides such as a silicon oxide, a silicon nitride, a silicon oxynitride, and an aluminum oxide. The organic insulating layer may include at least one of, for example, an acrylic resin, an epoxy resin, a phenol resin, a polyamide resin, a polyimide resin, an unsaturated polyester resin, a poly-phenylene ether resin, a poly-phenylene sulfide resin, and a benzocyclobutene resin. The passivation layer PSV may be provided as a single layer or a multilayer.

At least some of the various wires of the display panel DP and/or the display device DD may be further disposed on the passivation layer PSV.

The first via insulating layer VIA1 may be disposed on the passivation layer PSV. The first via insulating layer VIA1 may include an organic material. For example, the first via insulating layer VIA1 may include an organic insulating material such as an acrylic resin, an epoxy resin, a phenol resin, a polyamide resin, a polyimide resin, or the like within the spirit and the scope of the disclosure.

The first via insulating layer VIA1 may define a first hole pattern H1 that penetrates the first via insulating layer VIA1 and overlaps the first pixel opening PO1 in a plan view. The first hole pattern H1 may have a closed curved shape. For example, as shown in FIG. 6, the first hole pattern H1 may have a substantially donut shape or a substantially annular shape in a plan view. For example, the first hole pattern H1 may be symmetrical with respect to the center portion of the first pixel opening PO1 in a plan view.

The second via insulating layer VIA2 may be disposed on the first via insulating layer VIA1. The second via insulating layer VIA2 may include an organic material. For example, the second via insulating layer VIA2 may include an organic insulating material such as an acrylic resin, an epoxy resin, a phenol resin, a polyamide resin, a polyimide resin, or the like within the spirit and the scope of the disclosure.

The second via insulating layer VIA2 may cover the first via insulating layer VIA1. The second via insulating layer VIA2 may be configured to fill the first hole pattern H1 defined in the first via insulating layer VIA1. For example, in a first inclined area SL1 that overlaps the first hole pattern H1, the upper surface of the second via insulating layer VIA2 may be inclined. Here, the first inclined area SL1 may be an area corresponding to the area in which the first hole pattern H1 is disposed in a plan view.

The display element layer DPL may be disposed on the second via insulating layer VIA2. The display element layer DPL may include a first anode electrode AE1, a bank layer BNK, a first light emitting layer EL1, a cathode electrode CE, and an encapsulation layer TFE.

The first anode electrode AE1 may be disposed on the second via insulating layer VIA2. The first anode electrode AE1 may be electrically connected to the sub-pixel circuit SPC of the first sub-pixel SP1 through a through hole penetrating one or more of the insulating layers configuring the pixel circuit layer PCL.

The first anode electrode AE1 may include a conductive material having a selectable reflectivity. For example, the first anode electrode AE1 may include an opaque metal. For example, the first anode electrode AE1 may include metals such as silver (Ag), magnesium (Mg), aluminum (Al), platinum (Pt), palladium (Pd), gold (Au), nickel (Ni), neodymium (Nd), iridium (Ir), chromium (Cr), titanium (Ti), and an alloy thereof.

As described above, the upper surface of the second via insulating layer VIA2 in the first inclined area SL1 may have an inclination. For example, the upper surface of the first anode electrode AE1 disposed on the second via insulating layer VIA2 may have an inclination in the first inclined area SL1.

The bank layer BNK may be disposed on the second via insulating layer VIA2 and the first anode electrode AE1. The bank layer BNK may define the first pixel opening PO1 exposing a portion of the first anode electrode AE1. The bank layer BNK may be configured to include a light blocking material and may serve to prevent light mixing between adjacent sub-pixels. For example, the bank layer BNK may include an organic material. For example, the bank layer BNK may include an organic insulating material such as an acrylic resin, an epoxy resin, a phenol resin, a polyamide resin, a polyimide resin, or the like within the spirit and the scope of the disclosure.

The first light emitting layer EL1 may be disposed on the first anode electrode AE1 in the first pixel opening PO1. The first light emitting layer EL1 may include an organic light emitting material. For example, the first light emitting layer EL1 may include an organic light emitting material for generating light of a first color. The first light emitting layer EL1 may be provided as the light emitting element LD (see FIG. 2) of the first sub-pixel SP1.

As described above, the upper surface of the first anode electrode AE1 in the first inclined area SL1 may have an inclination. For example, the upper surface of the first light emitting layer EL1 disposed on the first anode electrode AE1 may have an inclination in the first inclined area SL1.

The cathode electrode CE may be disposed on the bank layer BNK and the first light emitting layer EL1. The cathode electrode CE may be entirely disposed on the bank layer BNK and the first light emitting layer EL1. The cathode electrode CE may be electrically connected to the second power voltage node VSSN (see FIG. 2). The second power voltage applied to the second power voltage node VSSN may be transmitted to the first light emitting layer EL1 through the cathode electrode CE.

The cathode electrode CE may be configured to be substantially transparent or translucent to satisfy a selectable light transmittance. For example, the cathode electrode CE may include at least one of various transparent conductive materials such as an indium tin oxide (ITO), an indium zinc oxide (IZO), a zinc oxide (ZnO), an indium gallium zinc oxide (IGZO), and an indium tin zinc oxide (ITZO).

As described above, the upper surface of the first light emitting layer EL1 in the first inclined area SL1 may have an inclination. For example, the upper surface of the cathode electrode CE disposed on the first light emitting layer EL1 may have an inclination in the first inclined area SL1.

The encapsulation layer TFE may be disposed on the cathode electrode CE. The encapsulation layer TFE may serve to protect components under or below the encapsulation layer TFE from external moisture and humidity. The encapsulation layer TFE may include a first inorganic encapsulation layer, an organic encapsulation layer, and a second inorganic encapsulation layer sequentially stacked on each other along the third direction DR3.

Referring back to FIG. 6 and FIG. 7, in the first inclined area SL1 corresponding to the first hole pattern H1, the upper surface of the first anode electrode AE1 may have an inclination. Light generated in the first light emitting layer EL1 may be reflected by the inclined surface of the first anode electrode AE1. For example, the light generated in the first light emitting layer EL1 may be provided in various directions intersecting the third direction DR3. Accordingly, the light generated by the first sub-pixel SP1 may be provided as light having substantially uniform luminance regardless of the direction in which the user of the display device DD looks at the display device DD. For example, side visibility of light generated by the first sub-pixel SP1 may become more uniform.

The first pixel opening PO1 may be circular in a plan view, and the first hole pattern H1 may have a substantially donut shape or a substantially annular shape symmetrical with respect to the center portion of the first pixel opening PO1 in a plan view. For example, the first inclined area SL1 corresponding to the first hole pattern H1 may also have a substantially donut shape or a substantially annular shape symmetrical with respect to the center portion of the first pixel opening PO1 in a plan view. According to the planar shapes of the first pixel opening PO1, the first hole pattern H1, and the first inclined area SL1, side visibility of light generated by the first sub-pixel SP1 may be more uniform.

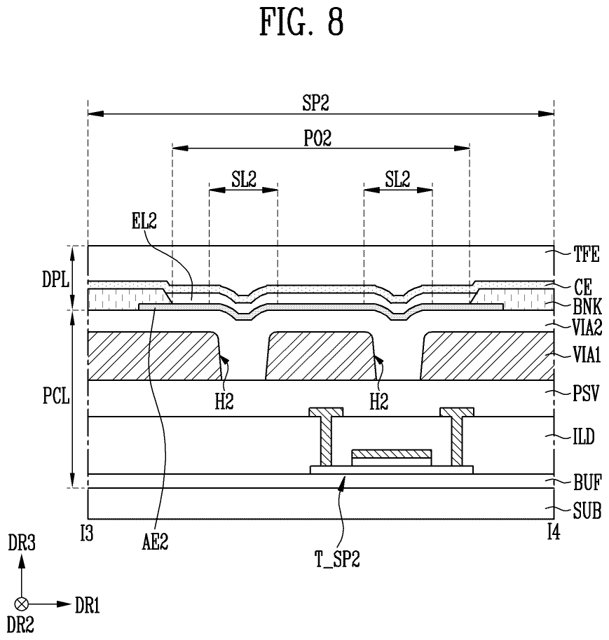

FIG. 8 illustrates a schematic cross-sectional view taken along line I3-I4 of FIG. 6.

Referring to FIG. 6 and FIG. 8, the second sub-pixel SP2 included in the pixel PXL is shown.

The second sub-pixel SP2 may include a substrate SUB, and a pixel circuit layer PCL and a display element layer DPL sequentially stacked on each other on the substrate SUB.

The pixel circuit layer PCL and various components included in the pixel circuit layer PCL may be configured substantially the same as (or similar to) those described with reference to FIG. 7. For example, the pixel circuit layer PCL may include insulating layers, semiconductor patterns, and conductive patterns stacked on each other on the substrate SUB.

As described with reference to FIG. 2, the sub-pixel circuit SPC (see FIG. 2) of the second sub-pixel SP2 may include transistors and one or more capacitors. The semiconductor patterns and conductive patterns of the pixel circuit layer PCL may function as transistors and capacitors of the sub-pixel circuit SPC. For example, the pixel circuit layer PCL may be provided with a second transistor T_SP2 corresponding to the second sub-pixel SP2. The second transistor T_SP2 may be configured substantially the same as (or similar to) the first transistor T_SP1 described with reference to FIG. 7. Accordingly, descriptions of redundant content are omitted. The conductive patterns of the pixel circuit layer PCL may further function as wires.

In the area in which the second sub-pixel SP2 is provided, the first via insulating layer VIA1 may define a second hole pattern H2 that penetrates the first via insulating layer VIA1 and overlaps the second pixel opening PO2 in a plan view. The second hole pattern H2 may have a closed curved shape. For example, as shown in FIG. 6, the second hole pattern H2 may have a substantially donut shape or a substantially annular shape in a plan view. For example, the second hole pattern H2 may be symmetrical with respect to the center portion of the second pixel opening PO2 in a plan view.

In the area in which the second sub-pixel SP2 is provided, the second via insulating layer VIA2 may be configured to cover the first via insulating layer VIA1 and fill the second hole pattern H2 defined in the first via insulating layer VIA1. For example, in a second inclined area SL2 that overlaps the second hole pattern H2, the upper surface of the second via insulating layer VIA2 may be inclined. Here, the second inclined area SL2 may be an area corresponding to the area in which the second hole pattern H2 is disposed in a plan view.

The display element layer DPL may be disposed on the second via insulating layer VIA2. The display element layer DPL may include a second anode electrode AE2, a bank layer BNK, a second light emitting layer EL2, a cathode electrode CE, and an encapsulation layer TFE.

The second anode electrode AE2 may be disposed on the second via insulating layer VIA2. The second anode electrode AE2 may be electrically connected to the sub-pixel circuit SPC of the second sub-pixel SP2 through a through hole penetrating one or more of the insulating layers configuring the pixel circuit layer PCL.

The second anode electrode AE2 may include a conductive material having a selectable reflectivity. For example, the second anode electrode AE2 may include substantially the same material as the first anode electrode AE1 described with reference to FIG. 7.

As described above, the upper surface of the second via insulating layer VIA2 in the second inclined area SL2 may have an inclination. For example, the upper surface of the second anode electrode AE2 disposed on the second via insulating layer VIA2 may have an inclination in the second inclined area SL2.

The bank layer BNK may be entirely provided across the first sub-pixel SP1 and the second sub-pixel SP2. The bank layer BNK may be disposed on the second via insulating layer VIA2 and the second anode electrode AE2. The bank layer BNK may define the second pixel opening PO2 exposing a portion of the second anode electrode AE1.

The second light emitting layer EL2 may be disposed on the second anode electrode AE2 in the second pixel opening PO2. The second light emitting layer EL2 may include an organic light emitting material. For example, the second light emitting layer EL2 may include an organic light emitting material for generating light of a second color. The second light emitting layer EL2 may be provided as the light emitting element LD (see FIG. 2) of the second sub-pixel SP2.

As described above, the upper surface of the second anode electrode AE2 in the second inclined area SL2 may have an inclination. For example, the upper surface of the second light emitting layer EL2 disposed on the second anode electrode AE2 may have an inclination in the second inclined area SL2.

The cathode electrode CE may be entirely provided throughout the first sub-pixel SP1 and the second sub-pixel SP2. The cathode electrode CE may be entirely disposed on the bank layer BNK and the second light emitting layer EL2. For example, the second power voltage applied to the second power voltage node VSSN may be transmitted to the second light emitting layer EL2 through the cathode electrode CE.

As described above, the upper surface of the second light emitting layer EL2 in the second inclined area SL2 may have an inclination. For example, the upper surface of the cathode electrode CE disposed on the second light emitting layer EL2 may have an inclination in the second inclined area SL2.

The encapsulation layer TFE may be entirely provided throughout the first sub-pixel SP1 and the second sub-pixel SP2. The encapsulation layer TFE may serve to be disposed on the cathode electrode CE to protect components under or below the encapsulation layer TFE from external moisture and humidity.

Referring back to FIG. 6 and FIG. 8, in the second inclined area SL2 corresponding to the second hole pattern H2, the upper surface of the second anode electrode AE2 may have an inclination. Light generated by the second light emitting layer EL2 may be reflected by the inclined surface of the second anode electrode AE2. For example, the light generated in the second light emitting layer EL2 may be provided in various directions intersecting the third direction DR3. Accordingly, the light generated by the second sub-pixel SP2 may be provided as light having substantially uniform luminance regardless of the direction in which the user of the display device DD looks at the display device DD. For example, side visibility of light generated by the second sub-pixel SP2 may become more uniform.

The second pixel opening PO2 may be circular in a plan view, and the second hole pattern H2 may have a substantially donut shape or a substantially annular shape symmetrical with respect to the center portion of the second pixel opening PO2 in a plan view. For example, the second inclined area SL2 corresponding to the second hole pattern H2 may also have a substantially donut shape or a substantially annular shape symmetrical with respect to the center portion of the second pixel opening PO2 in a plan view. According to the planar shapes of the first pixel opening PO2, the second hole pattern H2, and the second inclined area SL2, side visibility of light generated by the second sub-pixel SP2 may be more uniform.

Referring back to FIG. 7 and FIG. 8, in embodiments, a cross-sectional width of the second hole pattern H2 may be different from a cross-sectional width of the first hole pattern H1. For example, the cross-sectional width of the second hole pattern H2 may be greater than the cross-sectional width of the first hole pattern H1. As such, the cross-sectional widths of the hole patterns H1 and H2 may be provided differently depending on the type of the sub-pixels SP1 and SP2.

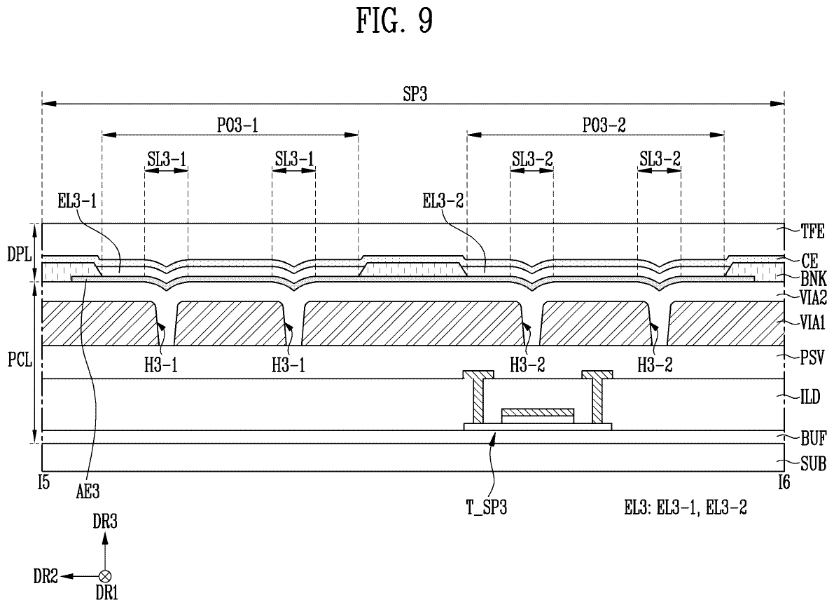

FIG. 9 illustrates a schematic cross-sectional view taken along line I5-I6 of FIG. 6.

Referring to FIG. 6 and FIG. 9, the third sub-pixel SP3 included in the pixel PXL is shown.

The third sub-pixel SP3 may include a substrate SUB, and a pixel circuit layer PCL and a display element layer DPL sequentially stacked on each other on the substrate SUB.

The pixel circuit layer PCL and various components included in the pixel circuit layer PCL may be configured substantially the same as (or similar to) those described with reference to FIG. 7. For example, the pixel circuit layer PCL may include insulating layers, semiconductor patterns, and conductive patterns stacked on each other on the substrate SUB.

As described with reference to FIG. 2, the sub-pixel circuit SPC (see FIG. 2) of the third sub-pixel SP3 may include transistors and one or more capacitors. The semiconductor patterns and conductive patterns of the pixel circuit layer PCL may function as transistors and capacitors of the sub-pixel circuit SPC. For example, the pixel circuit layer PCL may be provided with a third transistor T_SP3 corresponding to the third sub-pixel SP3. The third transistor T_SP3 may be configured substantially the same as (or similar to) the first transistor T_SP1 described with reference to FIG. 7. Accordingly, descriptions of redundant content are omitted. The conductive patterns of the pixel circuit layer PCL may further function as wires.

In the area in which the third sub-pixel SP3 is provided, the first via insulating layer VIA1 may define a third hole pattern H3 that penetrates the first via insulating layer VIA1 and overlaps the third pixel opening PO3 in a plan view. For example, the first via insulating layer VIA1 may define a (3-1)-th hole pattern H3-1 that overlaps the (3-1)-th pixel opening PO3-1 in a plan view and a (3-2)-th hole pattern H3-2 that overlaps the (3-2)-th pixel opening PO3-2 in a plan view. Each of the (3-1)-th hole pattern H3-1 and the (3-2)-th hole pattern H3-2 may have a closed curved shape. For example, each of the (3-1)-th hole pattern H3-1 and the (3-2)-th hole pattern H3-2 may have a substantially donut shape or a substantially annular shape in a plan view, as shown in FIG. 6. For example, the (3-1)-th hole pattern H3-1 may be symmetrical with respect to the center portion of the (3-1)-th pixel opening PO3-1 in a plan view, and the (3-2)-th hole pattern H3-2 may be symmetrical with respect to the center portion of the (3-2)-th pixel opening PO3-2 in a plan view.

In the area in which the third sub-pixel SP3 is provided, the second via insulating layer VIA2 may be configured to cover the first via insulating layer VIA1 and fill the third hole pattern H3 defined in the first via insulating layer VIA1. For example, in each of the (3-1)-th inclined area SL3-1 overlapping the (3-1)-th hole pattern H3-1 and the (3-2)-th inclined area SL3-2 overlapping the (3-2)-th hole pattern H3-2, the upper surface of the second via insulating layer VIA2 may have an inclination. Here, the (3-1)-th inclined area SL3-1 may be an area corresponding to an area in which the (3-1)-th hole pattern H3-1 is disposed in a plan view, and the (3-2)-th inclined area SL3-2 may be an area corresponding to an area in which the (3-2)-th hole pattern H3-2 is disposed in a plan view.

The display element layer DPL may be disposed on the second via insulating layer VIA2. The display element layer DPL may include a third anode electrode AE3, a bank layer BNK, a third light emitting layer EL3, a cathode electrode CE, and an encapsulation layer TFE.

The third anode electrode AE3 may be disposed on the second via insulating layer VIA2. The third anode electrode AE3 may be electrically connected to the sub-pixel circuit SPC of the third sub-pixel SP3 through a through hole penetrating one or more of the insulating layers configuring the pixel circuit layer PCL.

The third anode electrode AE3 may include a conductive material having a selectable reflectivity. For example, the third anode electrode AE3 may include substantially the same material as the first anode electrode AE1 described with reference to FIG. 7.

As described above, in the (3-1)-th and (3-2)-th inclined areas SL3-1 and SL3-2, the upper surface of the second via insulating layer VIA2 may have an inclination. For example, the upper surface of the third anode electrode AE3 disposed on the second via insulating layer VIA2 may have an inclination in the (3-1)-th inclined area SL3-1 and the (3-2)-th inclined area SL3-2.

The bank layer BNK may be entirely provided throughout the first to third sub-pixels SP1, SP2, and SP3. The bank layer BNK may be disposed on the second via insulating layer VIA2 and the third anode electrode AE3. The bank layer BNK may define a (3-1)-th pixel opening PO3-1 and a (3-2)-th pixel opening PO3-2 exposing portions of the third anode electrode AE3.

The third light emitting layer EL3 may include a (3-1)-th light emitting layer EL3-1 and a (3-2)-th light emitting layer EL3-2. The (3-1)-th light emitting layer EL3-1 may be disposed on the third anode electrode AE3 in the (3-1)-th pixel opening PO3-1. The (3-2)-th light emitting layer EL3-2 may be disposed on the third anode electrode AE3 in the (3-2)-th pixel opening PO3-2. The (3-1)-th light emitting layer EL3-1 and the (3-2)-th light emitting layer EL3-2 may include an organic light emitting material. For example, the (3-1)-th light emitting layer EL3-1 and the (3-2)-th light emitting layer EL3-2 may include an organic light emitting material for generating light of a third color. The (3-1)-th light emitting layer EL3-1 and the (3-2)-th light emitting layer EL3-2 may be provided as the light emitting element LD (see FIG. 2) of the third sub-pixel SP3.

As described above, the upper surface of the third anode electrode AE3 may have an inclination in the (3-1)-th inclined area SL3-1 and the (3-2)-th inclined area SL3-2. For example, the upper surface of the (3-1)-th light emitting layer EL3-1 and the upper surface of the (3-2)-th light emitting layer EL3-2 disposed on the third anode electrode AE3 may have an inclination in the (3-1)-th light emitting area SL3-1 and the (3-2)-th light emitting area SL3-2.

The cathode electrode CE may be entirely provided throughout the first to third sub-pixels SP1, SP2, and SP3. The cathode electrode CE may be entirely disposed on the bank layer BNK and the third light emitting layer EL3. For example, the second power voltage applied to the second power voltage node VSSN may be transmitted to the third light emitting layer EL3 through the cathode electrode CE.

As described above, the upper surface of the (3-1)-th light emitting layer EL3-1 and the upper surface of the (3-2)-th light emitting layer EL3-2 may have an inclination in the (3-1)-th inclined area SL3-1 and the (3-2)-th inclined area SL3-2. For example, the upper surface of the cathode electrode CE disposed on the (3-1)-th light emitting layer EL3-1 and the (3-2)-th light emitting layer EL3-2 may have an inclination in the (3-1)-th light emitting area SL3-1 and the (3-2)-th light emitting area SL3-2.

The encapsulation layer TFE may be entirely provided throughout the first to third sub-pixels SP1, SP2, and SP3. The encapsulation layer TFE may serve to be disposed on the cathode electrode CE to protect components under or below the encapsulation layer TFE from external moisture and humidity.

Referring back to FIG. 6 and FIG. 9, in the (3-1)-th inclined area SL3-1 and the (3-2)-th inclined area SL3-2 corresponding to the (3-1)-th hole pattern H3-1 and the (3-2)-th hole pattern H3-2, the upper surface of the third anode electrode AE3 may have an inclination. Light generated in the (3-1)-th light emitting layer EL3-1 and the (3-2)-th light emitting layer EL3-2 may be reflected by the inclined surfaces of the third anode electrode AE3. For example, light generated in the (3-1)-th light emitting layer EL3-1 and the (3-1)-th light emitting layer EL3-2 may be provided in various directions intersecting the third direction DR3. Accordingly, the light generated by the third sub-pixel SP3 may be provided as light having substantially uniform luminance regardless of the direction in which the user of the display device DD looks at the display device DD. For example, side visibility of light generated by the third sub-pixel SP3 may become more uniform.

The (3-1)-th pixel opening PO3-1 and the (3-2)-th pixel opening PO3-2 may be circular in a plan view, the (3-1)-th hole pattern H3-1 may have a substantially donut shape or a substantially annular shape symmetrical with respect to the center portion of the (3-1)-th pixel opening PO3-1 in a plan view, and the (3-2)-th hole pattern H3-2 may have a substantially donut shape or a substantially annular shape with respect to the center portion of the (3-2)-th pixel opening PO3-2 in a plan view. For example, the (3-1)-th inclined area SL3-1 corresponding to the (3-1)-th hole pattern H3-1 may also have a substantially donut shape or a substantially annular shape symmetrical with respect to the center portion of the (3-1)-th pixel opening PO3-1 in a plan view, and the (3-2)-th inclined area SL3-2 corresponding to the (3-2)-th hole pattern H3-2 may also have a substantially donut shape or a substantially annular shape symmetrical with respect to the center portion of the (3-2)-th pixel opening PO3-2 in a plan view. According to the planar shapes of the (3-1)-th pixel opening PO3-1, the (3-2)-th pixel opening PO3-2, the (3-1)-th hole pattern H3-1, the (3-2)-th hole pattern H3-2, the (3-1)-th inclined area SL3-1, and the (3-2)-th inclined area SL3-2, side visibility of light generated in the third sub-pixel SP3 may be more uniform.

Referring back to FIG. 7 and FIG. 9, in embodiments, the cross-sectional width of the (3-1)-th hole pattern H3-1 may be different from the cross-sectional width of the first hole pattern H1, and the cross-sectional width of the (3-2)-th hole pattern H3-2 may be different from the cross-sectional width of the first hole pattern H1. For example, the cross-sectional width of the (3-1)-th hole pattern H3-1 may be smaller than the cross-sectional width of the first hole pattern H1, and the cross-sectional width of the (3-2)-th hole pattern H3-2 may be smaller than the cross-sectional width of the first hole pattern H1. As such, the cross-sectional widths of the hole patterns H1, H3-1, and H3-2 may be provided differently depending on the type of the sub-pixels SP1 and SP3.

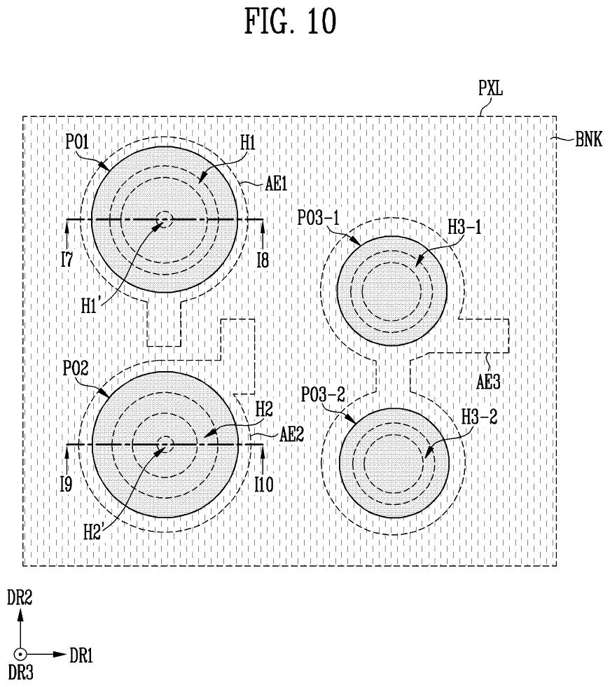

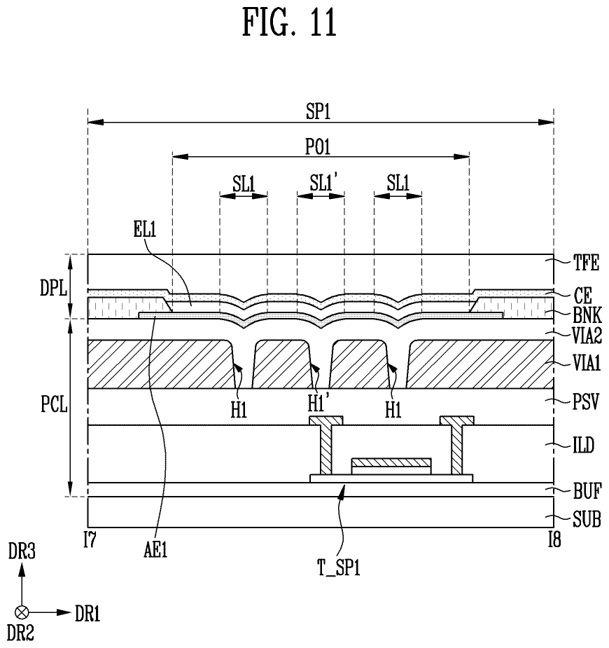

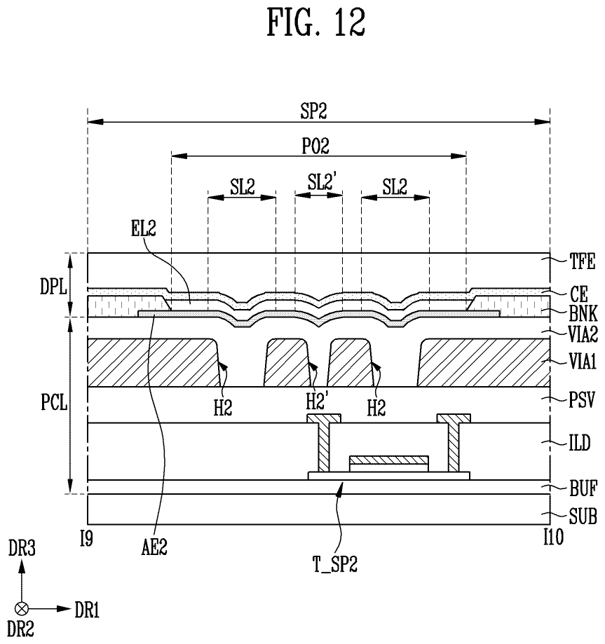

FIG. 10 illustrates a schematic top plan view for explaining a second embodiment of one of pixels included in the display panel of FIG. 3. FIG. 11 illustrates a schematic cross-sectional view taken along line I7-I8 of FIG. 10. FIG. 12 illustrates a schematic cross-sectional view taken along line I9-I10 of FIG. 10.

Hereinafter, the description will be made focusing on the differences compared to the embodiment described with reference to FIG. 6 to FIG. 9, and the omitted description will be replaced with the previous description.

Referring to FIG. 10 and FIG. 11, the first via insulating layer VIA1 may further define a first additional hole pattern H1′ that penetrates the first via insulating layer VIA1 and overlaps the first pixel opening PO1 in a plan view. The first additional hole pattern H1′ may be circular in a plan view, as shown in FIG. 10. For example, the first additional hole pattern H1′ may be surrounded by the first hole pattern H1 in a plan view. The first additional hole pattern H1′ may be disposed, for example, at the center portion of the first pixel opening PO1 in a plan view.

The second via insulating layer VIA2 may be configured to fill the first additional hole pattern H1′. For example, in the first additional inclined area SL1′ overlapping the first additional hole pattern H1′, the upper surface of the second via insulating layer VIA2 may have an inclination. Here, the first additional inclined area SL1′ may be an area corresponding to an area in which the first additional hole pattern H1′ is disposed in a plan view.

The upper surface of the first anode electrode AE1 disposed on the second via insulating layer VIA2 may have an inclination in the first additional inclined area SL1′. The upper surface of the first light emitting layer EL1 disposed on the first anode electrode AE1 may have an inclination in the first additional inclined area SL1′. The upper surface of the cathode electrode CE disposed on the first light emitting layer EL1 may have an inclination in the first additional inclined area SL1′.

As such, as the first additional hole pattern H1′ and the first additional inclined area SL1′ are further defined, side visibility of light generated by the first sub-pixel SP1 may become more uniform.

Referring to FIG. 10 and FIG. 12, the first via insulating layer VIA1 may further define a second additional hole pattern H2′ that penetrates the first via insulating layer VIA1 and overlaps the second pixel opening PO2 in a plan view. The second additional hole pattern H2′ may be circular in a plan view, as shown in FIG. 10. For example, the second additional hole pattern H2′ may be surrounded by the second hole pattern H2 in a plan view. The second additional hole pattern H2′ may be disposed, for example, at the center portion of the second pixel opening PO2 in a plan view.

The second via insulating layer VIA2 may be configured to fill the second additional hole pattern H2′. For example, in the second additional inclined area SL2′ overlapping the second additional hole pattern H2′, the upper surface of the second via insulating layer VIA2 may have an inclination. Here, the second additional inclined area SL2′ may be an area corresponding to an area in which the second additional hole pattern H2′ is disposed in a plan view.

The upper surface of the second anode electrode AE1 disposed on the second via insulating layer VIA2 may have an inclination in the second additional inclined area SL2′. The upper surface of the second light emitting layer EL2 disposed on the second anode electrode AE2 may have an inclination in the second additional inclined area SL2′. The upper surface of the cathode electrode CE disposed on the second light emitting layer EL2 may have an inclination in the second additional inclined area SL2′.

As such, as the second additional hole pattern H2′ and the second additional inclined area SL2′ are further defined, side visibility of light generated by the second sub-pixel SP2 may become more uniform.

Referring back to FIG. 10 to FIG. 12, the first via insulating layer VIA1 may further define an additional hole pattern (for example, H1′ or H2′), in at least one of an area in which the first sub-pixel SP1 is provided, an area in which the second sub-pixel SP2 is provided, and an area in which the third sub-pixel SP3 is provided. Accordingly, side visibility of light generated in the pixel PXL may become more uniform compared to the embodiment described with reference to FIG. 6 to FIG. 9.

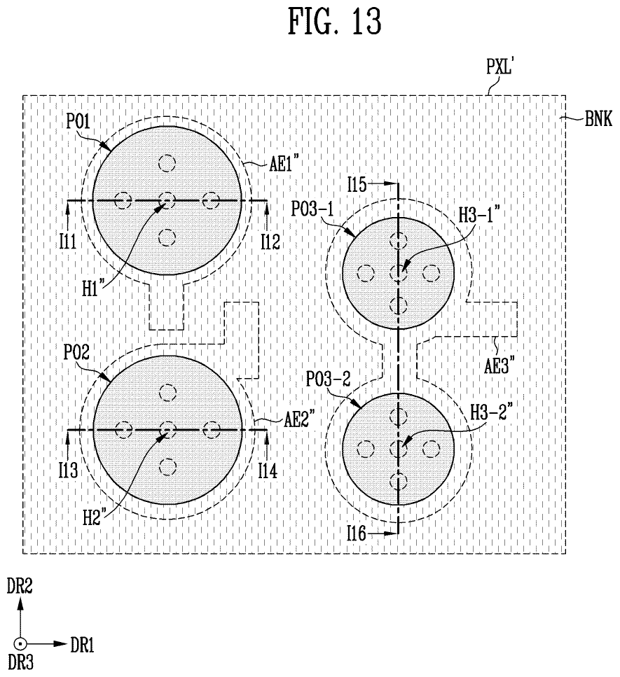

FIG. 13 illustrates a schematic top plan view for explaining a third embodiment of one of pixels included in the display panel of FIG. 3.

Referring to FIG. 13, a pixel PXL′ may include first to third anode electrodes AE1″, AE2″, and AE3″. The first anode electrode AE1″ may be spaced apart from the second anode electrode AE2″ in the second direction DR2. The third anode electrode AE3″ may be spaced apart from the first and second anode electrodes AE1″ and AE2″ in the first direction DR1. However, the arrangement of the first to third anode electrodes AE1″, AE2″, and AE3″ is not limited thereto, and may vary according to embodiments. For example, the first to third anode electrodes AE1″, AE2″, and AE3″ may be arranged or disposed in a zigzag pattern.

The first anode electrode AE1″ may be provided as the anode electrode AE (see FIG. 2) included in the sub-pixel circuit SPC (see FIG. 2) of the first sub-pixel SP1″. The second anode electrode AE2″ may be provided as the anode electrode AE (see FIG. 2) included in the sub-pixel circuit SPC (see FIG. 2) of the second sub-pixel SP2″. The third anode electrode AE3″ may be provided as the anode electrode AE (see FIG. 2) included in the sub-pixel circuit SPC (see FIG. 2) of the third sub-pixel SP3″.

The bank layer BNK may be disposed on the first to third anode electrodes AE1″, AE2″, and AE3″. The bank layer BNK may define a first pixel opening PO1 exposing a portion of the first anode electrode AE1″, a second pixel opening PO2 exposing a portion of the second anode electrode AE2″, and a third pixel opening PO3 exposing a portion of the third anode electrode AE3″.

Each of the first to third pixel openings PO1, PO2, and PO3 may be circular in a plan view. Accordingly, each of the exposed surfaces of the first to third anode electrodes AE1″, AE2″, and AE3″ exposed by the first to third pixel openings PO1, PO2, and PO3 may be circular in a plan view. Accordingly, light generated by the first to third sub-pixels SP1″, SP2″, and SP3″ including the first to third anode electrodes AE1″, AE2″, and AE3″ may be provided as light having substantially uniform luminance regardless of the direction in which the user of the display device DD looks at the display device DD.

In embodiments, first to third pixel openings PO1, PO2, and PO3 may be provided, each independently. For example, as shown in FIG. 13, the third pixel opening PO3 may include a (3-1)-th pixel opening PO3-1 and a (3-2)-th pixel opening PO3-2. The (3-1)-th pixel opening PO3-1 and the (3-2)-th pixel opening PO3-2 may be spaced apart from each other. Each of the (3-1)-th pixel opening PO3-1 and the (3-2)-th pixel opening PO3-2 may be circular in a plan view. Accordingly, each of the exposed surfaces of the third anode electrode AE3″ exposed by the (3-1)-th pixel opening PO3-1 and the (3-2)-th pixel opening PO3-2 may be circular in a plan view.

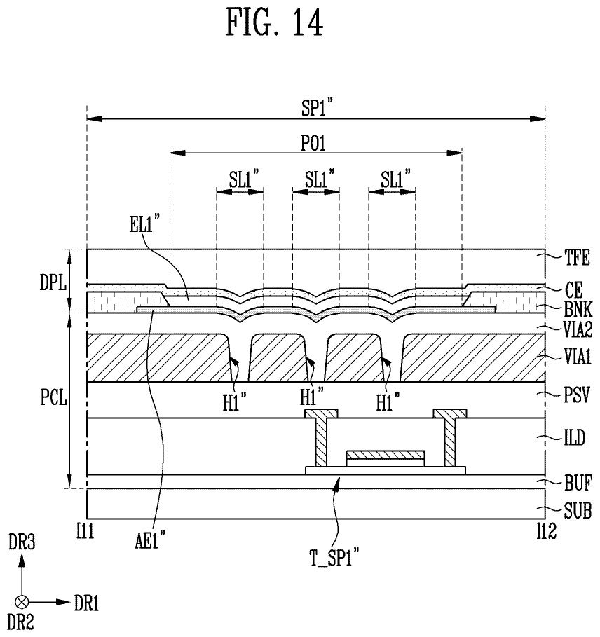

FIG. 14 illustrates a schematic cross-sectional view taken along line I11-I12 of FIG. 13.

Referring to FIG. 13 and FIG. 14, the first sub-pixel SP1″ included in the pixel PXL′ is shown.

The first sub-pixel SP1″ may include a substrate SUB, and a pixel circuit layer PCL and a display element layer DPL sequentially stacked on each other on the substrate SUB.

The pixel circuit layer PCL and various components included in the pixel circuit layer PCL may be configured substantially the same as (or similar to) those described with reference to FIG. 7. For example, the pixel circuit layer PCL may include insulating layers, semiconductor patterns, and conductive patterns stacked on each other on the substrate SUB.

As described with reference to FIG. 2, the sub-pixel circuit SPC (see FIG. 2) of the first sub-pixel SP1″ may include transistors and one or more capacitors. The semiconductor patterns and conductive patterns of the pixel circuit layer PCL may function as transistors and capacitors of the sub-pixel circuit SPC. For example, a first transistor T_SP1″ corresponding to the first sub-pixel SP1″ may be provided in the pixel circuit layer PCL. The first transistor T_SP1″ may be configured substantially the same as (or similar to) the first transistor T_SP1 described with reference to FIG. 7. Accordingly, descriptions of redundant content are omitted. The conductive patterns of the pixel circuit layer PCL may further function as wires.

The first via insulating layer VIA1 may define first hole patterns H1″ that penetrates the first via insulating layer VIA1 and overlaps the first pixel opening PO1 in a plan view. In a plan view, each of the first hole patterns H1″ may be circular. The first hole patterns H1″ may include, for example, one first central hole pattern disposed at the center portion of the first pixel opening PO1 in a plan view and first peripheral hole patterns disposed around the first central hole pattern. For example, the first peripheral hole patterns may be disposed symmetrically with respect to the first central hole pattern in a plan view.

The second via insulating layer VIA2 may be configured to cover the first via insulating layer VIA1 and fill the first hole patterns H1″ defined in the first via insulating layer VIA1. For example, the upper surface of the second via insulating layer VIA2 may have an inclination in the first inclined areas SL1″ that overlap the first hole patterns H1″. Here, the first inclined areas SL1″ may be areas corresponding to areas in which the first hole patterns H1″ are disposed in a plan view.

The display element layer DPL may be disposed on the second via insulating layer VIA2. The display element layer DPL may include a first anode electrode AE1″, a bank layer BNK, a first light emitting layer EL1″, a cathode electrode CE, and an encapsulation layer TFE.

The first anode electrode AE1″ may be disposed on the second via insulating layer VIA2. The first anode electrode AE1″ may be electrically connected to the sub-pixel circuit SPC of the first sub-pixel SP1″ through a through hole penetrating one or more of the insulating layers configuring the pixel circuit layer PCL.

The first anode electrode AE1″ may include a conductive material having a selectable reflectivity. For example, the first anode electrode AE1″ may include an opaque metal. For example, the first anode electrode AE1″ may include metals such as silver (Ag), magnesium (Mg), aluminum (Al), platinum (Pt), palladium (Pd), gold (Au), nickel (Ni), neodymium (Nd), iridium (Ir), chromium (Cr), titanium (Ti), and an alloy thereof.

As described above, the upper surface of the second via insulating layer VIA2 in the first inclined areas SL1″ may have an inclination. For example, the upper surface of the first anode electrode AE1″ disposed on the second via insulating layer VIA2 may have an inclination in the first inclined areas SL1″.

The bank layer BNK may be disposed on the second via insulating layer VIA2 and the first anode electrode AE1″. The bank layer BNK may define the first pixel opening PO1 exposing a portion of the first anode electrode AE1″. The bank layer BNK may be configured to include a light blocking material and may serve to prevent light mixing between adjacent sub-pixels. For example, the bank layer BNK may include an organic material. For example, the bank layer BNK may include an organic insulating material such as an acrylic resin, an epoxy resin, a phenol resin, a polyamide resin, a polyimide resin, or the like within the spirit and the scope of the disclosure.

The first light emitting layer EL1″ may be disposed on the first anode electrode AE1″ in the first pixel opening PO1. The first light emitting layer EL1″ may include an organic light emitting material. For example, the first light emitting layer EL1″ may include an organic light emitting material for generating light of a first color. The first light emitting layer EL1″ may be provided as the light emitting element LD (see FIG. 2) of the first sub-pixel SP1″.

As described above, the upper surface of the first anode electrode AE1″ in the first inclined area SL1″ may have an inclination. For example, the upper surface of the first light emitting layer EL1″ disposed on the first anode electrode AE1″ may have an inclination in the first inclined areas SL1″.

The cathode electrode CE may be disposed on the bank layer BNK and the first light emitting layer EL1″. The cathode electrode CE may be entirely disposed on the bank layer BNK and the first light emitting layer EL1″. The cathode electrode CE may be electrically connected to the second power voltage node VSSN (see FIG. 2). The second power voltage applied to the second power voltage node VSSN may be transmitted to the first light emitting layer EL1″ through the cathode electrode CE.

The cathode electrode CE may be configured to be substantially transparent or translucent to satisfy a selectable light transmittance. For example, the cathode electrode CE may include at least one of various transparent conductive materials such as an indium tin oxide (ITO), an indium zinc oxide (IZO), a zinc oxide (ZnO), an indium gallium zinc oxide (IGZO), and an indium tin zinc oxide (ITZO).

As described above, the upper surface of the first light emitting layer EL1″ in the first inclined areas SL1″ may have an inclination. For example, the upper surface of the cathode electrode CE disposed on the first light emitting layer EL1″ may have an inclination in the first inclined areas SL1″.

The encapsulation layer TFE may be disposed on the cathode electrode CE. The encapsulation layer TFE may serve to protect components under or below the encapsulation layer TFE from external moisture and humidity. The encapsulation layer TFE may include a first inorganic encapsulation layer, an organic encapsulation layer, and a second inorganic encapsulation layer sequentially stacked on each other along the third direction DR3.

Referring back to FIG. 13 and FIG. 14, in the first inclined areas SL1″ corresponding to the first hole patterns H1″, the upper surface of the first anode electrode AE1″ may have an inclination. Light generated by the first light emitting layer EL1″ may be reflected by the inclined surfaces of the first anode electrode AE1″. For example, the light generated in the first light emitting layer EL1″ may be provided in various directions intersecting the third direction DR3. Accordingly, the light generated by the first sub-pixel SP1″ may be provided as light having substantially uniform luminance regardless of the direction in which the user of the display device DD looks at the display device DD. For example, side visibility of light generated by the first sub-pixel SP1″ may become more uniform.

The first pixel opening PO1 may be circular in a plan view, and the first hole patterns H1″ may be symmetrically disposed with respect to the center portion of the first pixel opening PO1 in a plan view. For example, the first inclined areas SL1″ corresponding to the first hole patterns H1″ may also be symmetrically disposed with respect to the center portion of the first pixel opening PO1 in a plan view. According to the disposition of the first pixel opening PO1, the first hole patterns H1″, and the first inclined areas SL1″, the side visibility of the light generated in the first sub-pixel SP1″ may be more uniform.

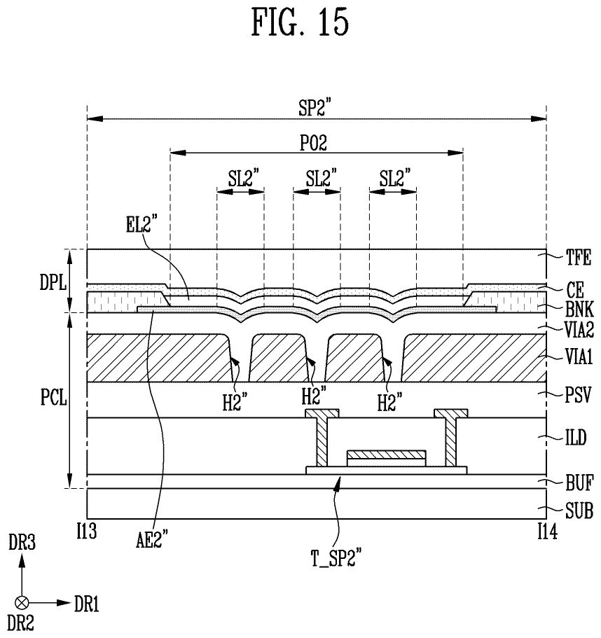

FIG. 15 illustrates a schematic cross-sectional view taken along line I13-I14 of FIG. 13.

Referring to FIG. 13 and FIG. 15, the second sub-pixel SP2″ included in the pixel PXL′ is shown.

The second sub-pixel SP2″ may include a substrate SUB, and a pixel circuit layer PCL and a display element layer DPL sequentially stacked on each other on the substrate SUB.

The pixel circuit layer PCL and various components included in the pixel circuit layer PCL may be configured substantially the same as (or similar to) those described with reference to FIG. 7. For example, the pixel circuit layer PCL may include insulating layers, semiconductor patterns, and conductive patterns stacked on each other on the substrate SUB.

As described with reference to FIG. 2, the sub-pixel circuit SPC (see FIG. 2) of the second sub-pixel SP2″ may include transistors and one or more capacitors. The semiconductor patterns and conductive patterns of the pixel circuit layer PCL may function as transistors and capacitors of the sub-pixel circuit SPC. For example, a second transistor T_SP2″ corresponding to the second sub-pixel SP2″ may be provided in the pixel circuit layer PCL. The second transistor T_SP2″ may be configured substantially the same as (or similar to) the first transistor T_SP1 described with reference to FIG. 7. Accordingly, descriptions of redundant content are omitted. The conductive patterns of the pixel circuit layer PCL may further function as wires.

In the area in which the second sub-pixel SP2″ is provided, the first via insulating layer VIA1 may define second hole patterns H2″ that penetrates the first via insulating layer VIA1 and overlaps the second pixel opening PO2 in a plan view. In a plan view, each of the second hole patterns H2″ may be circular. The second hole patterns H2″ may include, for example, one second central hole pattern disposed at the center portion of the second pixel opening PO2 in a plan view and second peripheral hole patterns disposed around the second central hole pattern. For example, the second peripheral hole patterns may be disposed symmetrically with respect to the second central hole pattern in a plan view.

In the area in which the second sub-pixel SP2″ is provided, the second via insulating layer VIA2 may be configured to cover the first via insulating layer VIA1 and fill the second hole patterns H2″ defined in the first via insulating layer VIA1. For example, the upper surface of the second via insulating layer VIA2 may have an inclination in the second inclined areas SL2″ that overlap the second hole patterns H2″. Here, the second inclined areas SL2″ may be areas corresponding to areas in which the second hole patterns H2″ are disposed in a plan view.

The display element layer DPL may be disposed on the second via insulating layer VIA2. The display element layer DPL may include a second anode electrode AE2″, a bank layer BNK, a second light emitting layer EL2″, a cathode electrode CE, and an encapsulation layer TFE.

The second anode electrode AE2″ may be disposed on the second via insulating layer VIA2. The second anode electrode AE2″ may be electrically connected to the sub-pixel circuit SPC of the second sub-pixel SP2″ through a through hole penetrating one or more of the insulating layers configuring the pixel circuit layer PCL.

The second anode electrode AE2″ may include a conductive material having a selectable reflectivity. For example, the second anode electrode AE2″ may include substantially the same material as the first anode electrode AE1 described with reference to FIG. 7.

As described above, the upper surface of the second via insulating layer VIA2 in the second inclined areas SL2″ may have an inclination. For example, the upper surface of the second anode electrode AE2″ disposed on the second via insulating layer VIA2 may have an inclination in the second inclined areas SL2″.

The bank layer BNK may be entirely provided throughout the first sub-pixel SP1″ and the second sub-pixel SP2″. The bank layer BNK may be disposed on the second via insulating layer VIA2 and the second anode electrode AE2″. The bank layer BNK may define the second pixel opening PO2 exposing a portion of the second anode electrode AE2″.

The second light emitting layer EL2″ may be disposed on the second anode electrode AE2″ in the second pixel opening PO2. The second light emitting layer EL2″ may include an organic light emitting material. For example, the second light emitting layer EL2″ may include an organic light emitting material for generating light of a second color. The second light emitting layer EL2″ may be provided as the light emitting element LD (see FIG. 2) of the second sub-pixel SP2″.

As described above, the upper surface of the second anode electrode AE2″ in the second inclined area SL2″ may have an inclination. For example, the upper surface of the second light emitting layer EL2″ disposed on the second anode electrode AE2″ may have an inclination in the second inclined areas SL2″.

The cathode electrode CE may be entirely provided throughout the first sub-pixel SP1″ and the second sub-pixel SP2″. The cathode electrode CE may be entirely disposed on the bank layer BNK and the second light emitting layer EL2″. For example, the second power voltage applied to the second power voltage node VSSN may be transmitted to the second light emitting layer EL2″ through the cathode electrode CE.

As described above, the upper surface of the second light emitting layer EL2″ in the second inclined areas SL2″ may have an inclination. For example, the upper surface of the cathode electrode CE disposed on the second light emitting layer EL2″ may have an inclination in the second inclined areas SL2″.

The encapsulation layer TFE may be entirely provided throughout the first sub-pixel SP1″ and the second sub-pixel SP2″. The encapsulation layer TFE may serve to be disposed on the cathode electrode CE to protect components under or below the encapsulation layer TFE from external moisture and humidity.

Referring back to FIG. 13 and FIG. 15, in the second inclined areas SL2″ corresponding to the second hole patterns H2″, the upper surface of the second anode electrode AE2″ may have an inclination. Light generated in the second light emitting layer EL2″ may be reflected by the inclined surfaces of the second anode electrode AE2″. For example, the light generated in the second light emitting layer EL2″ may be provided in various directions intersecting the third direction DR3. Accordingly, the light generated in the second sub-pixel SP2″ may be provided as light having substantially uniform luminance regardless of the direction in which the user of the display device DD looks at the display device DD. For example, the side visibility of light generated in the second sub-pixel SP2″ may become more uniform.

The second pixel opening PO2 may be circular in a plan view, and the second hole patterns H2″ may be symmetrically disposed with respect to the center portion of the second pixel opening PO2 in a plan view. For example, the second inclined areas SL2″ corresponding to the second hole patterns H2″ may also be symmetrically disposed with respect to the center portion of the second pixel opening PO2 in a plan view. According to the disposition of the second pixel opening PO2, the second hole patterns H2″, and the second inclined areas SL2″, the side visibility of the light generated in the second sub-pixel SP2″ may be more uniform.

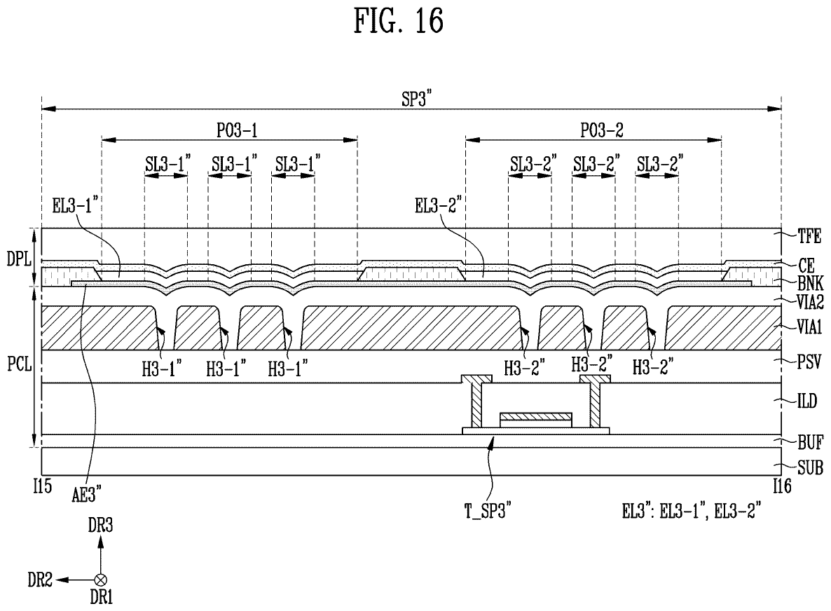

FIG. 16 illustrates a schematic cross-sectional view taken along line I15-I16 of FIG. 13.

Referring to FIG. 13 and FIG. 16, the third sub-pixel SP3″ included in the pixel PXL′ is shown.

The third sub-pixel SP3″ may include a substrate SUB, and a pixel circuit layer PCL and a display element layer DPL sequentially stacked on each other on the substrate SUB.

The pixel circuit layer PCL and various components included in the pixel circuit layer PCL may be configured substantially the same as (or similar to) those described with reference to FIG. 7. For example, the pixel circuit layer PCL may include insulating layers, semiconductor patterns, and conductive patterns stacked on each other on the substrate SUB.

As described with reference to FIG. 2, the sub-pixel circuit SPC (see FIG. 2) of the third sub-pixel SP3″ may include transistors and one or more capacitors. The semiconductor patterns and conductive patterns of the pixel circuit layer PCL may function as transistors and capacitors of the sub-pixel circuit SPC. For example, a third transistor T_SP3″ corresponding to the third sub-pixel SP3″ may be provided in the pixel circuit layer PCL. The third transistor T_SP3″ may be configured substantially the same as (or similar to) the first transistor T_SP1 described with reference to FIG. 7. Accordingly, descriptions of redundant content are omitted. The conductive patterns of the pixel circuit layer PCL may further function as wires.

In the area in which the third sub-pixel SP3″ is provided, the first via insulating layer VIA1 may define third hole patterns H3″ that penetrates the first via insulating layer VIA1 and overlaps the third pixel opening PO3 in a plan view. For example, the first via insulating layer VIA1 may define (3-1)-th hole patterns H3-1″ that overlaps the (3-1)-th pixel opening PO3-1 in a plan view and (3-2)-th hole patterns H3-2″ that overlaps the (3-2)-th pixel opening PO3-2 in a plan view. In a plan view, each of the (3-1)-th hole patterns H3-1″ and the (3-2)-th hole patterns H3-2″ may be circular. The (3-1)-th hole patterns H3-1″ may include, for example, one (3-1)-th central hole pattern disposed at the center portion of the (3-1)-th pixel opening PO3-1 in a plan view and (3-1)-th peripheral hole patterns disposed around the (3-1)-th central hole pattern. In a plan view, the (3-1)-th peripheral hole patterns may be symmetrically disposed with respect to the (3-1)-th central hole pattern. The (3-2)-th hole patterns H3-2″ may include, for example, one (3-2)-th central hole pattern disposed at the center portion of the (3-2)-th pixel opening PO3-2 in a plan view and (3-2)-th peripheral hole patterns disposed around the (3-2)-th central hole pattern. In a plan view, the (3-2)-th peripheral hole patterns may be symmetrically disposed with respect to the (3-1)-th central hole pattern.

In the area in which the third sub-pixel SP3″ is provided, the second via insulating layer VIA2 may be configured to cover the first via insulating layer VIA1 and fill the (3-1)-th hole patterns H3-1″ and the (3-2)-th hole patterns H3-2″ defined in the first via insulating layer VIA1. For example, in each of the (3-1)-th inclined areas SL3-1″ overlapping the (3-1)-th hole patterns H3-1″ and the (3-2)-th inclined areas SL3-2″ overlapping the (3-2)-th hole pattern H3-2″, the upper surface of the second via insulating layer VIA2 may have an inclination. Here, the (3-1)-th inclined areas SL3-1″ may be areas corresponding to an area in which the (3-1)-th hole patterns H3-1″ are disposed in a plan view, and the (3-2)-th inclined areas SL3-2″ may be areas corresponding to an area in which the (3-2)-th hole patterns H3-2″ are disposed in a plan view.

The display element layer DPL may be disposed on the second via insulating layer VIA2. The display element layer DPL may include a third anode electrode AE3″, a bank layer BNK, a third light emitting layer EL3″, a cathode electrode CE, and an encapsulation layer TFE.

The third anode electrode AE3″ may be disposed on the second via insulating layer VIA2. The third anode electrode AE3″ may be electrically connected to the sub-pixel circuit SPC of the third sub-pixel SP3″ through a through hole penetrating one or more of the insulating layers configuring the pixel circuit layer PCL.

The third anode electrode AE3″ may include a conductive material having a selectable reflectivity. For example, the third anode electrode AE3″ may include substantially the same material as the first anode electrode AE1 described with reference to FIG. 7.

As described above, in the (3-1)-th inclined areas SL3-1″ and the (3-2)-th inclined areas SL3-2″, the upper surface of the second via insulating layer VIA2 may have an inclination. For example, the upper surface of the third anode electrode AE3″ disposed on the second via insulating layer VIA2 may have an inclination in the (3-1)-th inclined areas SL3-1″ and the (3-2)-th inclined areas SL3-2″.

The bank layer BNK may be entirely provided throughout the first to third sub-pixels SP1″, SP2″, and SP3″. The bank layer BNK may be disposed on the second via insulating layer VIA2 and the third anode electrode AE3″. The bank layer BNK may define a (3-1)-th pixel opening PO3-1 and a (3-2)-th pixel opening PO3-2 exposing portions of the third anode electrode AE3″.

The third light emitting layer EL3″ may include a (3-1)-th light emitting layer EL3-1″ and a (3-2)-th light emitting layer EL3-2″. The (3-1)-th light emitting layer EL3-1″ may be disposed on the third anode electrode AE3″ in the (3-1)-th pixel opening PO3-1. The (3-2)-th light emitting layer EL3-2″ may be disposed on the third anode electrode AE3″ in the (3-2)-th pixel opening PO3-2. The (3-1)-th light emitting layer EL3-1″ and the (3-2)-th light emitting layer EL3-2″ may include an organic light emitting material. For example, the (3-1)-th light emitting layer EL3-1″ and the (3-2)-th light emitting layer EL3-2″ may include an organic light emitting material for generating light of a third color. The (3-1)-th light emitting layer EL3-1″ and the (3-2)-th light emitting layer EL3-2″ may be provided as the light emitting element LD (see FIG. 2) of the third sub-pixel SP3″.

As described above, the upper surface of the third anode electrode AE3″ may have an inclination in the (3-1)-th inclined areas SL3-1″ and the (3-2)-th inclined areas SL3-2″. For example, the upper surface of the (3-1)-th light emitting layer EL3-1″ and the upper surface of the (3-2)-th light emitting layer EL2″ disposed on the third anode electrode AE3″ may have an inclination in the (3-1)-th light emitting area SL3-1″ and the (3-2)-th light emitting area SL3-2″.

The cathode electrode CE may be entirely provided throughout the first to third sub-pixels SP1″, SP2″, and SP3″. The cathode electrode CE may be entirely disposed on the bank layer BNK and the third light emitting layer EL3″. For example, the second power voltage applied to the second power voltage node VSSN may be transmitted to the third light emitting layer EL3″ through the cathode electrode CE.

As described above, the upper surface of the (3-1)-th light emitting layer EL3-1″ and the upper surface of the (3-2)-th light emitting layer EL3-2″ may have an inclination in the (3-1)-th inclined areas SL3-1″ and the (3-2)-th inclined areas SL3-2″. For example, the upper surface of the cathode electrode CE disposed on the (3-1)-th light emitting layer EL3-1″ and the (3-2)-th light emitting layer EL3-2″ may have an inclination in the (3-1)-th light emitting areas SL3-1″ and the (3-2)-th light emitting areas SL3-2″.

The encapsulation layer TFE may be entirely provided throughout the first to third sub-pixels SP1″, SP2″, and SP3″. The encapsulation layer TFE may serve to be disposed on the cathode electrode CE to protect components under or below the encapsulation layer TFE from external moisture and humidity.

Referring back to FIG. 13 and FIG. 16, in the (3-1)-th inclined areas SL3-1″ and the (3-2)-th inclined areas SL3-2″ corresponding to the (3-1)-th hole patterns H3-1″ and the (3-2)-th hole pattern H3-2″, the upper surface of the third anode electrode AE3″ may have an inclination. Light generated in the (3-1)-th light emitting layer EL3-1″ and the (3-2)-th light emitting layer EL3-2″ may be reflected by the inclined surfaces of the third anode electrode AE3″. For example, light generated in the (3-1)-th light emitting layer EL3-1″ and the (3-1)-th light emitting layer EL3-2″ may be provided in various directions intersecting the third direction DR3. Accordingly, the light generated in the third sub-pixel SP3″ may be provided as light having substantially uniform luminance regardless of the direction in which the user of the display device DD looks at the display device DD. For example, the side visibility of light generated in the third sub-pixel SP3″ may become more uniform.

The (3-1)-th pixel opening PO3-1 and the (3-2)-th pixel opening PO3-2 may be circular in a plan view, the (3-1)-th hole patterns H3-1″ may be disposed to be symmetrical with respect to the center portion of the (3-1)-th pixel opening PO3-1 in a plan view, and the (3-2)-th hole pattern H3-2″ may be disposed to be symmetrical with respect to the center portion of the (3-2)-th pixel opening PO3-2 in a plan view. For example, the (3-1)-th inclined areas SL3-1″ corresponding to the (3-1)-th hole patterns H3-1″ may also be disposed to be symmetrical with respect to the center portion of the (3-1)-th pixel opening PO3-1 in a plan view, and the (3-2)-th inclined areas SL3-2″ corresponding to the (3-2)-th hole patterns H3-2″ may also be disposed to be symmetrical with respect to the center portion of the (3-2)-th pixel opening PO3-2 in a plan view. According to the disposition of the (3-1)-th pixel opening PO3-1, the (3-2)-th pixel opening PO3-2, the (3-1)-th hole patterns H3-1″, the (3-2)-th hole patterns H3-2″, the (3-1)-th inclined areas SL3-1″, and the (3-2)-th inclined areas SL3-2″, side visibility of light generated in the third sub-pixel SP3 may be more uniform.

A display device according to an embodiment is applicable to various types of electronic devices. In an embodiment, an electronic device includes the above-described display device and may further include other modules or devices having additional functions in addition to the display device.

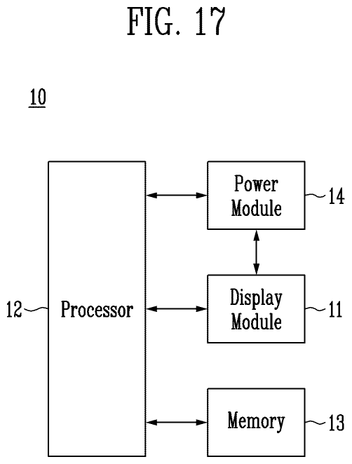

FIG. 17 is a block diagram of an electronic device according to an embodiment. Referring to FIG. 17, the electronic device 10 may include a display module 11, a processor 12, a memory 13, and a power module 14.

The processor 12 may include at least one of a central processing unit (CPU), an application processor (AP), a graphic processing unit (GPU), a communication processor (CP), an image signal processor (ISP), and a controller.

The memory 13 may store data and/or information used to operate the processor 12 or the display module 11. In case that the processor 12 executes an application stored in the memory 13, image data signals and/or input control signals may be transferred to the display module 11. The display module 11 may process the provided signals and output image information on a display screen.

The power module 14 may include a power supply module, such as a power adapter or a battery device, and a power conversion module. The power conversion module may convert power supplied by the power supply module and generate power to operate the electronic device 10.

At least one of the above-described components of the electronic device 10 may be included in the display device according to embodiments as described above. In terms of functionality, some of the individual modules included in one module may be included in the display device and others may be provided separately from the display device. For example, the display module 11 may be included in the display device, whereas the processor 12, the memory 13, and the power module 14 are not included in the display device and are instead provided separately in the electronic device 10.

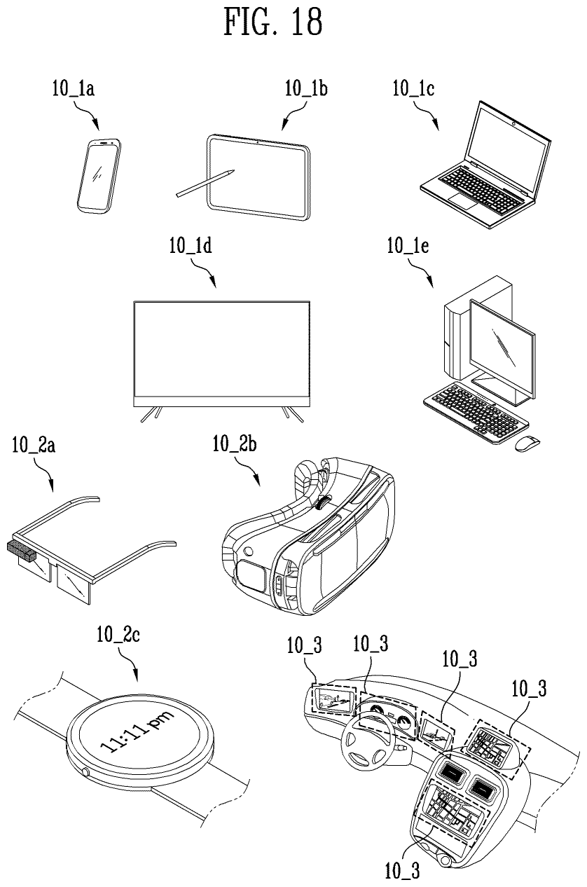

FIG. 18 shows schematic views of various embodiments of an electronic device.

Referring to FIG. 18, various types of electronic devices to which embodiments of a display device are applied may include an electronic device to display images such as a smartphone 10_1a, a tablet PC 10_1b, a laptop computer 10_1c, a television (TV) 10_1d, and a desktop monitor 10_1e, a wearable electronic device including a display module such as smart glasses 10_2a, a head-mounted display (HMD) 10_2b, and a smart watch 10_2c, and an automotive electronic device 10_3 including a display module such as a center information display (CID) disposed at the instrument cluster, the center fascia, and the dashboard of a vehicle, and a room mirror display.

While this disclosure has been described, it is to be understood that the disclosure is not limited to the disclosed embodiments, but, on the contrary, is intended to cover various modifications and equivalent arrangements included within the spirit and scope of the disclosure and of the appended claims.

What is claimed is:

1. A display device comprising:
a pixel circuit layer including a first via insulating layer and a second via insulating layer covering the first via insulating layer;
an anode electrode disposed on the second via insulating layer; and
a bank layer including a pixel opening exposing a portion of the anode electrode,
wherein the first via insulating layer includes a hole pattern that penetrates the first via insulating layer and overlaps the pixel opening in a plan view, and
an upper surface of the anode electrode has an inclination in an area overlapping the hole pattern.

2. The display device of claim 1, wherein
the second via insulating layer fills the hole pattern of the first via insulating layer.

3. The display device of claim 2, wherein
an upper surface of the second via insulating layer has an inclination in the area overlapping the hole pattern.

4. The display device of claim 1, wherein
the pixel opening is substantially circular in a plan view.

5. The display device of claim 4, wherein
the hole pattern has a substantially donut shape or a substantially annular shape in a plan view.

6. The display device of claim 5, wherein
the hole pattern is substantially symmetrical with respect to a center portion of the pixel opening in a plan view.

7. The display device of claim 5, wherein
an additional hole pattern penetrating the first via insulating layer is included in the first via insulating layer, and
an upper surface of the anode electrode has an inclination in an area overlapping the additional hole pattern.

8. The display device of claim 7, wherein
the additional hole pattern is surrounded by the hole pattern in a plan view.

9. The display device of claim 7, wherein
the second via insulating layer fills the additional hole pattern of the first via insulating layer.

10. The display device of claim 9, wherein
an upper surface of the second via insulating layer has an inclination in the area that overlaps the additional hole pattern.

11. The display device of claim 7, wherein
the additional hole pattern is disposed at a center portion of the pixel opening in a plan view.

12. The display device of claim 1, further comprising:
a light emitting layer disposed on the anode electrode in the pixel opening.

13. The display device of claim 12, wherein
in the area overlapping the hole pattern, an upper surface of the light emitting layer has an inclination.

14. A display device comprising:
a pixel circuit layer including a first via insulating layer and a second via insulating layer covering the first via insulating layer;
an anode electrode disposed on the second via insulating layer; and
a bank layer including a pixel opening exposing a portion of the anode electrode,
wherein the first via insulating layer includes a plurality of hole patterns that penetrate the first via insulating layer and overlap the pixel opening in a plan view, and
an upper surface of the anode electrode has an inclination in areas overlapping the plurality of hole patterns.

15. The display device of claim 14, wherein
the second via insulating layer fills the plurality of hole patterns of the first via insulating layer.

16. The display device of claim 15, wherein
an upper surface of the second via insulating layer has an inclination in the areas that overlap the plurality of hole patterns.

17. The display device of claim 14, wherein
the pixel opening is substantially circular in a plan view.

18. The display device of claim 17, wherein
each of the plurality of hole patterns is substantially circular in a plan view.

19. The display device of claim 18, wherein
the plurality of hole patterns include a central hole pattern disposed at a center portion of the pixel opening, and peripheral hole patterns disposed around the central hole pattern in a plan view.

20. The display device of claim 19, wherein
the peripheral hole patterns are symmetrically disposed with respect to the central hole pattern in a plan view.

21. An electronic device, comprising:
a display device that displays an image, the display device including:
a pixel circuit layer including a first via insulating layer and a second via insulating layer covering the first via insulating layer;
an anode electrode disposed on the second via insulating layer; and
a bank layer including a pixel opening exposing a portion of the anode electrode,
wherein the first via insulating layer includes a hole pattern that penetrates the first via insulating layer and overlaps the pixel opening in a plan view, and
an upper surface of the anode electrode has an inclination in an area overlapping the hole pattern.

22. The electronic device of claim 21, wherein
the second via insulating layer fills the hole pattern of the first via insulating layer.

23. The electronic device of claim 21, wherein
the pixel opening is substantially circular in a plan view.
